(19) United States
(12) Patent Application Publication
(10) Pub. No.: US 2023/0112010 A1
(43) Pub. Date: Apr. 13, 2023

(54) CAPILLARY BRIDGE ENHANCED FLUID GRIP DEVICE

(71) Applicant: BVW Holding AG, Cham (CH)

(72) Inventors: Michael Milbocker, Holliston, MA (US); Lukas Bluecher, Eurasberg (DE); Roelof Trip, Atlanta, GA (US)

(21) Appl. No.: 17/953,681

(22) Filed: Sep. 27, 2022

Related U.S. Application Data
(60) Provisional application No. 63/248,671, filed on Sep. 27, 2021.

(51) Int. Cl. B81B 3/00; C09J 9/00

(52) U.S. Cl. CPC B81B 3/0054; C09J 9/00; B81B 2203/0109; C09J 2301/31

(57) ABSTRACT

A microstructured surface is disclosed capable of immobilizing or resisting displacement forces with respect to a target surface. The microstructured surface is capable of generating capillary bridges with a target surface. The capillary bridges can be further stabilized to generate a novel liquid enhanced adhesion mechanism.

A portion of the disclosure of this patent document contains material that is subject to copyright protection. The copyright owner has no objection to the reproduction of the patent document or the patent disclosure, as it appears in the U.S. Patent and Trademark Office patent file or records, but otherwise reserves all copyright rights whatsoever.

### CROSS-REFERENCES TO RELATED APPLICATIONS

This application claims benefit of the following patent application(s) which is/are hereby incorporated by reference: 63/248,671 filed on Sep. 27, 2021

### STATEMENT REGARDING FEDERALLY SPONSORED RESEARCH OR DEVELOPMENT

Not Applicable

### REFERENCE TO SEQUENCE LISTING OR COMPUTER PROGRAM LISTING APPENDIX

Not Applicable

### BACKGROUND OF THE INVENTION

The present invention relates generally to a device having a microstructured surface.

More particularly, this invention pertains to a device having a microstructured surface that generates capillary bridges between a target surface and the microstructured surface.

A capillary bridge may be understood as a minimized surface of liquid or membrane, created between two surfaces having a partial or fully wetted interface between the surfaces. When the interface volume between the two surfaces is filled with a compound fluid, capillary bridges also may form between two liquids. A compound fluid can be a mixture of immiscible or partially miscible fluids, liquids and gases, or solids and gases. When multiple capillary bridges touch, their shapes can be the result of a mutual reduction in surface energy between components of the compound liquid.

Capillary shapes can be classified by several known shapes (1) nodoid with ‘neck’, (2) catenoid, (3) unduloid with ‘neck’, (4) cylinder, (5) unduloid with ‘haunch’ (6) sphere and (7) nodoid with ‘haunch’. The shape of the capillary bridge can determine whether the bridge is attractive or repulsive regarding the attachment points.

There are three primary types of capillary bridges. There can be capillary bridges formed between parallel planar surfaces, capillary bridges connecting a planar surface to a spherical surface, and lastly, capillary bridges connecting a planar surface to a concave spherical surface.

Embodiments as disclosed herein provide microstructured surfaces that are capable of creating capillary bridges between the microstructured surface and a target surface that can generate adhesive forces between the two surfaces.

### BRIEF SUMMARY OF THE INVENTION

In some embodiments, liquid solution phase separation in the gaps between microstructures, especially between hierarchically arranged microstructures of separate dimensions, can be used as a free energy system of a compound liquid solution self-organized by the localized surface potential of the microstructures. The nonequilibrium local bulk chemical free energy density may drive the self-organizing phase separation.

In some embodiments, each fluid phase may be anchored to a microstructure with a characteristic surface energy potential. Assuming all the phases comprising the compound fluid are separated by a miscibility gap, then each fluid phase may tend to form its own capillary bridge. The surface energies (substance and dimensions) of the microstructures may be selected to correspond to these miscibility gaps in order to induce capillary bridges that may tend to resist disruption, and hence resist lateral translation.

To obtain a good correspondence one need solve the corresponding Landau-type free energy function corresponding to the energy landscape. The energy minima may define the spatial position occupied by the liquid phase, as capillary bridges between either the microstructured surface and the target surface, and/or capillary bridges formed between microstructures.

For partially miscible phase components the concentration gradient at the interfaces between capillary bridges may be important, and may be expressed as the molar fraction of two adjacent phases. The gradient terms in the free energy equation may describe the energy contributions from liquid-liquid and liquid-microstructure interfaces. In a refined model, the surface potentials are modelled as smooth transitions as diffuse interfaces at both liquid-liquid interfaces and liquid-microstructure interfaces.

Inside the capillary bridges of certain embodiments, the free energy function may be described as a double-well potential for binary interfacing solutions with a miscibility gap. Parameters such as the pitch, diameter and aspect ratio of the microstructures can be used to control the fluid-fluid and fluid-microstructure interfacial energy densities.

In certain embodiments, the microstructured surfaces may be self-organizing and may use philic-phobic domains to assist heterogeneous nucleation of phase separation processes. In particular, a microstructure may possess an asymmetry intended to initiate phase nucleation.

For example, in one embodiment, a pillar array may be arranged on the top of a larger pillar and may have the peripheral pillars pointed and the inner pillars flat-topped. Assuming the phase separation process is approximately isothermal, the phase separation may be described by the Cahn-Hilliard equation.

In some embodiments, the microstructure surface may be self-stabilizing through phase domains caused by the microstructure contact with the compound fluid interaction volume. The capillary bridges anchored on microstructures may avoid the usual coarsening process as usually observed during phase separation, in which Laplace pressure inside a droplet decreases as it grows bigger, thus bigger droplets may grow at the expense of smaller ones.

For embodiments comprising microstructure-stabilized capillary bridges, inter-liquid diffusion may decrease the size of bigger bridges (with higher internal pressure) and may feed the growth of smaller ones (with lower internal pressure), which may create negative feedback for the growth of capillary bridges and may equilibrate their sizes.

The localization of the microstructured device on the target surface may be greatly enhanced when the microstructures are arranged hierarchically. In some embodiments, they may span at least two orders of dimensional magnitude, for example from 10 to 1000 microns.

In certain embodiments, asymmetry of the microstructures can also play an important role in the stabilization of the Wenzel-Cassie structured capillary bridges. It is known the Laplace pressure across a curved interface may lead to chemical potential shift in the liquid mixture in accord with the Gibbs-Duhem relation. The chemical potential is higher and nonuniform inside bigger and unsymmetric capillary bridges. It is this nonuniform chemical potential distribution that drives the bigger bridges to shrink and become symmetric.

It is a general feature of capillary bridges that they interact with each other through inter-liquid diffusion and ultimately achieve equilibrium of uniform pressure and chemical potential. Such an effect is of critical importance since it implies an intrinsic self-stabilization mechanism among adjacent capillary bridges through diffusion.

### BRIEF DESCRIPTION OF THE SEVERAL VIEWS OF THE DRAWINGS

FIG. 1 is an illustration of the relationship between the microstructure geometry and the capillary bridge geometry.

FIG. 2 is a depiction of surface energy microstructure without a morphological microstructure.

FIG. 3 is a depiction of the contact angles for a capillary bridge attached to a liquid infused surface (LIS).

FIG. 4 is a depiction of the geometry of a capillary bridge between a microstructured surface and a target surface.

FIG. 5 is a depiction of a system for capillary bridge narrowing.

FIG. 6 is a depiction of a range of stable isoclines for a capillary bridge.

FIG. 7 is a depiction of a mushroom profile hierarchical microstructured surface.

FIG. 8 is a depiction of depinning of capillary bridges resulting in translation of the microstructured surface relative to the target surface.

FIG. 9 is a depiction of microstructured surface where the capillary bridges are variously oriented to generate normal and lateral restorative forces.

FIG. 10 is a depiction of the normal and lateral forces created by capillary bridges.

FIG. 11 is a depiction of a doubly reentrant microstructured surface of the present invention.

FIG. 12 is a depiction of a mutually stabilized pinning mechanism for a bi-phasic immiscible fluid interface.

FIG. 13 is a depiction of a reverse capillary bridge microstructure.

### DETAILED DESCRIPTION OF THE INVENTION

The following description and examples illustrate some exemplary embodiments of the disclosed invention in detail. Those of skill in the art will recognize that there are numerous variations and modifications of this invention that are encompassed by its scope. Accordingly, the description of a certain exemplary embodiment should not be deemed to limit the scope of the present invention.

In order to facilitate an understanding of the disclosed invention and embodiments, a number of terms are defined below.

The term “capillary bridge,” as used herein, may refer to a minimized surface of liquid or membrane which may be created between two bodies with an arbitrary shape.

The term “chemical microstructure surface,” as used herein, may refer to a microstructured surface where the different microstructures may comprise different chemical domains of a microstructured surface, wherein each microstructured domain may have a distinct and different surface energy.

The term “compound fluid,” as used herein, may refer to a fluid composed of two or more phases.

The term “contact angle,” as used herein, may refer to the angle, conventionally measured through the stationary liquid, where a liquid—vapor interface meets a solid surface. At the moment of translation of the liquid in constant with a solid surface, the advancing contact angle may be represented by θ_{A} and the receding contact angle may be represented by θ_{R}. In some embodiments, it may be informative to use the term intrinsic (Young's) contact angle to refer to the contact angle which may be a pure substance with a uniform surface energy (on the micron scale). The term “structured contact angle” as used herein may refer to the contact area made with a pure substance with a uniformly varying surface energy, and the term “apparent contact angle” may refer to any contact angle where the surface energy of the contacting surface may be either randomly varying or incompletely characterized and specific to a particular testing apparatus.

The term “contact angle hysteresis,” as used herein, may refer to the difference between the advancing contact angle θ_{A} and the receding contact angle θ_{R}. The term may be mathematically defined as θ_{A}-θ_{R} although the term may also be used to describe the expression cos θ_{R}−cos θ_{A}.

The term “hierarchical microstructure,” as used herein, may refer to a microstructured surface where there may be a number of microstructures characterized by a dimensional range. For example, a hierarchical surface may have a first set of microstructures with dimensions between 10-50 microns and a second set of microstructures between 250-500 microns, but such example is not limiting, as additional examples are disclosed herein. Generally, one may understand that hierarchical microstructures may be in a stacked configuration. However, other configurations are also possible that still result in a “hierarchical” arrangement. Stacked hierarchical microstructured surfaces may include the next smaller dimension microstructure level positioned on a surface of the present microstructure.

The term “hydrophilic substance,” as used herein, may refer to a molecule or other molecular entity that may be attracted to water molecules and may tend to be dissolved in water.

The term “hydrophobic substance,” as used herein, may refer to a molecule or other molecular entity that may be repellant to water molecules and may tend to not be dissolved in water.

The term “hydrophilic solid surface,” as used herein, may refer to, in some aspects, a surface where the contact angle with water may be less than 75 degrees.

The term “hydrophobic solid surface,” as used herein, may refer to, in some aspects, a surface where the contact angle with water may be greater than 75 degrees.

The term “superhydrophobic solid surface,” as used herein, may refer to, in some aspects, a surface where the contact angle with water may be greater than 150 degrees.

The term “interaction volume,” as used herein, may refer to the space between a microstructured surface and a target surface which may be composed of a gas, liquid, or solid particulates, and/or one or more of these individually or in combination.

The term “liquid enhanced adhesion,” as used herein, may refer to a state in which the interface between a microstructured device and a target surface may be stabilized against translation of the microstructured device relative to the target surface. In some embodiments, there may be two types of liquid enhanced adhesion, where one may be resistant to shear displacement, and the other may be resistance to peel force.

The term “morphological microstructure surface,” as used herein, may refer to a microstructured surface where different microstructures domains may comprise different topologically sculpted domains of a microstructured surface wherein each microstructured domain may have a distinct and different surface energy.

The term “phase,” as used herein, may refer to a component of an interaction volume of a different chemical nature (surface energy) than all the other components of the interaction volume.

The term “philic,” as used herein, may refer to a general term meaning attractive with respect to the preceding modifier, such as hydrophilic being attractive to water, or may generally refer to an attractive composition.

The term “phobic,” as used herein, may refer to a general term meaning repellant with respect to the preceding modifier, such as hydrophobic being repellant to water, or may generally refer to a repellant composition.

The term “sessile drop,” and/or “sessile drop technique,” as used herein, may refer to a method used for the characterization of solid surface energies by determining the contact angle hysteresis. The main premise of the method may be understood that by placing a droplet of liquid with a known surface energy, the shape of the drop, specifically the contact angle, and the known surface energy of the liquid may be parameters which can be used to calculate the surface energy of the solid sample. The liquid used for such experiments may be referred to as the probe liquid. When the probe liquid is not specified, it may be assumed the probe liquid is purified or distilled water. Another method for determining the contact angle hysteresis includes the tilt method, but the effects of gravity should be subtracted from the observed advancing and receding contact angle. In this disclosure, the two methods may be understood to be generally mathematically equivalent.

The term “suck down,” as used herein, may refer to a mechanism that may occur when a microstructured device and a target surface are contacted through an interaction volume which may subsequently generate a normal force which may push the two surfaces together.

The term “surface energy,” or “surface free energy,” or “interfacial free energy,” as used herein, may refer to quantification of the disruption of intermolecular bonds that may occur when a surface is created. One method of quantification may be quantification of the contact angle of the surface.

The term “target oriented capillary bridge,” as used herein, may refer to a capillary bridge where at least some of the liquid volume in the capillary bridge may be displaced toward the target surface of the fluid bridging a microstructured surface to a target surface.

The term “microstructure oriented capillary bridge,” as used herein, may refer to a capillary bridge where at least some of the liquid volume in the capillary bridge may be displaced toward the microstructured surface of the fluid bridging a microstructured surface to a target surface.

The term “Wenzel-Cassie capillary bridge,” as used herein, may refer to a specific capillary bridge structure that may form on a distinct microstructure domain of a microstructured surface.

The term “Wenzel-Cassie interface,” as used herein, may refer to a structuring of an interaction volume such that hydrophobic constituents may migrate to lower surface energy surface domains and hydrophilic constituents may migrate to higher surface energy surface domains. The term may be generally applied to phobic and philic definitions, where these constituents are juxtaposed on different microstructured levels.

The term “Wenzel-Cassie microstructure,” as used herein, may refer to a microstructure surface where some surface domains may have a higher surface energy than other surface domains.

The term “wetting,” as used herein, may refer to the ability of a liquid to maintain contact with a solid surface, which may result from intermolecular interactions when the two are brought together. The degree of wetting (wettability) may be determined by a force balance between adhesive and cohesive forces in some embodiments.

The term “Young-Laplace equation,” as used herein, may refer to a nonlinear partial differential equation that may be used to describe the capillary pressure difference sustained across an interface between two static fluids, such as water and air, due to the phenomenon of surface tension and/or wall tension.

The term “zeroth order microstructure,” as used herein, may refer to the first microstructure level proximal to the surface of a microstructured substrate. The next and smaller dimensional level may be referred to as the first order microstructure level, and so on. In various embodiments and examples, the microstructure levels may not necessarily be stacked.

### OVERVIEW

The embodiments described herein relate generally to devices, systems, and methods for creating stable capillary bridges using microstructured surfaces which may generate adhesive characteristics to a target surface. It will be appreciated that capillary bridges may be understood as minimal surface energy structures. Accordingly, the shape(s) of these capillary bridges may be influenced by external factors or influences, such as, in one example, the force/direction of gravity. In turn, the shape of the capillary bridge may dictate the attractive or repulsive forces generated by the capillary bridge, or in some cases, may change/modify the attractive or repulsive forces generated by the capillary bridge. In some embodiments described herein, a bridging substance may be included that may be a liquid or a gas. The embodiments described below may include an enclosing boundary, which may also be called the interface surface of the capillary bridge. In certain embodiments below, the interface may be characterized by a uniform surface tension.

Capillary interface surfaces may produce strong adhesion between the capillary bridges due to a mechanism which minimizes mutual surface tension as well as Laplace pressure. Capillary bridges can form as a result of phase transition, e.g., by liquid in vapor condensation, while capillary bridges can also be formed by two immiscible liquid phases. The liquids can be partially miscible, and hence the stability of the capillary bridges formed can depend on the difference between the mixing miscibility and the surface energy of the capillary bridges.

Generally, if two liquid phases are insoluble in each other, mechanical agitation may be required to distribute the preferential liquid phase into the tiny gaps between particles to form liquid bridges. But when the anchor points are to microstructures on a microstructured device the capillary bridges can self-assemble. Because these capillary bridges spontaneously form a lower energy state, such a state requires energy to be disrupted, i.e., to disrupt the capillary bridge that has formed. In embodiments disclosed herein, certain aspects of these novel mechanisms responsible for liquid enhanced adhesion between the target surface and the microstructured device may be described. In certain embodiments, capillary bridges may also be formed in a pure liquid mixed with a gaseous component.

In some embodiments, generation of capillary bridges may be through binary liquid phase separation. Such a method may be used to stabilize a microstructured surface against a target surface through capillary bridge formation in a Wenzel-Cassie configuration. The Wenzel-Cassie configuration may comprise phobic-phase capillary bridges formed adjacent to philic-phase capillary bridges. In some embodiments, this juxtaposition may be possible because the hierarchically arranged microstructures may include stacked levels of microfeatures with different surface energy.

It may be known that capillary bridges can form without hierarchical microstructures, however, capillary bridges formed via hierarchically arranged microstructures may tend to be self-stabilizing across a range of dimensional scales. It will be appreciated that the hierarchical structure may tend to avoid liquid clustering phenomena frequently observed in compound liquid interfaces. Additionally, coarsening of the phase domains may be a general phenomenon in phase separation, which is likely avoided by the microstructured surfaces disclosed herein.

The usual capillary coarsening problem involving the equilibrium state of a liquid meniscus can be described by the Kelvin equation which links individual radii of curvature of liquid surface to the ambient vapor pressure. Because the ambient vapor pressure is usually constant, the interaction among different menisci is rarely considered.

As disclosed in various embodiments below, several remarkable properties of Wenzel-Cassie structured capillary bridge systems can be found in multi-phase liquid interface volumes bridging a microstructured surface device to a target surface.

A Wenzel-Cassie structured capillary bridge system may be defined as a self-stabilization mechanism that can operate through diffusive equilibrium of two-phase liquid morphologies. In certain embodiments, adjacent capillary bridges may interact with each other through diffusion. Such a self-stabilization mechanism may automatically stabilize the spontaneously formed capillary bridges anchored on neighboring microstructures during liquid solution phase separation, in contrast to the usual coarsening processes which can occur in the absence of the microstructured device. The hierarchical arrangement of the microstructures may render the capillary bridges with dramatically enhanced microstructural stability and self-reinforcing characteristics, which is important for a practical route to in-situ localization of a microstructured device to a target surface with a liquid/fluid interface.

### Hierarchical Microstructures

This disclosure provides a microstructured surface that may generate a self-similar pinning mechanism unique to hierarchical microstructures. To aid in the design of a pinning microstructure the total pinned length of the contact lines at each level of the hierarchical pattern may be taken into account.

When considering an interaction volume on a microstructure surface comprising multiple levels of microfeatures, the apparent macroscopic contact line of the interaction volume comprises not only the zeroth level of hierarchy, but may be divided into many smaller contact lines, each sitting on top of a microfeature at the first level.

The receding angle exhibited by the capillary bridges local to the first level of hierarchy may be different from that exhibited by an interaction volume observed at the zeroth level. If the contact lines of these first-level capillary bridges are observed at an even smaller length scale, it may be understood that they may be divided into even smaller contact lines, each sitting on top of a microfeature at the second level of hierarchy. The receding angle of these second-level capillary bridges local to the second level of hierarchy may in turn be different from that observed at the first level scale. This self-similar pattern of subdivided contact lines and differing local contact angles may be continued down successive levels until reaching a level “n” that exhibits a homogeneous wetting interface.

At this cutoff level, the contact line on each roughness feature will be continuous. Thus, the actual pinned length of the apparent contact line at any level may be determined by the geometry of the roughness features at all smaller levels, if they exist. The apparent contact line at any level can be projected onto the tops of the roughness features of the next smaller-scale level.

In certain embodiments disclosed herein, the projected contact line may typically traverse a number of individual microfeature elements. This hypothetical interaction volume may be pinned to the peripheral micropillars, to the interior micropillars, or to both. In some embodiments, significant distortion may occur only at the micropillars that sit directly under the projected contact line.

It may be understood that in some embodiments, the total pinned length may be the perimeter of each micropillar multiplied by the number of peripheral micropillars (for a compound liquid the periphery may exist at every phase separation interface).

In certain embodiments, the interface between a microstructured surface and the target surface may comprise only a pure fluid. In such instances, the effective pinned fraction of a projected length of the contact line may then equal the product of the number of peripheral micropillars and the perimeter of the micropillars divided by the projected length of the contact line. Or in terms of pitch, the pinned fraction may be the perimeter of the micropillars divided by the pitch. In embodiments where the microfeatures are sparsely spaced, only a small fraction of the projected contact line may be pinned. However, in embodiments where the pillars are packed densely, then the pinned fraction may increase. In some cases, the pinned fraction may be greater than 1, meaning that the sum of the lengths of the contact lines of the peripheral capillary bridges may be greater than the length of the projected contact line.

In some embodiments, applying the pinned fraction concept to structures with multiple hierarchies, it may be necessary to project the contact lines of the j-th level bridges onto the tops of the j+1-th level features to find the number of peripheral capillary bridges. It follows, the total pinned fraction of a macroscopic contact line at the zeroth level can be calculated for a surface with “n” hierarchical roughness levels by the product of the pinned fraction at each level. Similarly, the total pinned length may be equal to the sum of the lengths of contact lines of all the peripheral capillary bridges at the n-th hierarchical level.

It may be understood that the total pinned fraction may not always increase with increasing hierarchical levels. For instance, this may explain why the hierarchical structure of the lotus leaf is non-pinning to fluid. However, as disclosed herein, values of pitch between microfeatures can be chosen that give additive results, leading to high levels of pinning.

In some embodiments, the adhesion force of an interfacial fluid volume to a hierarchical microstructured surface with discrete microfeatures can be determined, in some cases, by considering the force due to surface tension acting along the target and microstructured anchors of the capillary bridges.

In embodiments where the interface includes a pure liquid, the adhesion of the entire interaction volume may be predominantly dictated by the vertical component of surface tension acting at the peripheral capillary bridges. For embodiments including a compound liquid, the periphery may occur at the interface between phase boundaries. In such environments, adding a small amount of a lipid to a pure water interface can increase the adhesion force by a factor of 10 or more. Embodiments of the present disclosure in such environments may yield the paradoxical phenomenon of liquid enhanced grip.

It will be appreciated from this disclosure that the force pinning a single capillary bridge at the j-th level can be written as the integral of the surface tension times the local contact angle integrated over the perimeter of an individual microfeature onto which the bridge is pinned in some embodiments. In some examples, the vertical adhesion force of the entire contact volume can be approximated by summing the forces due to all of the peripheral nth-level capillary bridges.

For some embodiments, to analyze the cutoff between when an integral decreases and then increases for increasing number of hierarchy levels, one can start by normalizing the vertical adhesion force by the adhesion force for an interaction volume with an equivalent base radius on a smooth surface. The resulting ratio may be the force multiplier that reflects the strength of the pinning on the microstructured surface as compared with that on a smooth surface.

In embodiments with a self-similarity condition, the adhesion force per unit length of a single capillary bridge atop a feature at the j-th level may be the same as that of a single capillary bridge sitting on a surface consisting of a texture with levels j+1 through “n.” Based on such embodiments where the capillary bridges are sparse, they effectively may not interact with one another to a large degree, and the adhesion force may decrease with an increasing number of hierarchy levels.

In embodiments where the capillary bridges are at denser spacings, because the microfeatures are more closely spaced the peripheral capillary bridges may interact with one another. In certain embodiments, this may lead to a larger local receding angle between adjacent pillars, thus increasing the contact angle hysteresis.

Experiments reveal additional microfeature levels may increase the adhesion force per length when the normalized pinned fraction at that level is greater than one. As the pinned fraction of a particular level may increase beyond one, that level may act to increase the adhesion force per unit length. However, in some embodiments, the adhesion force may be saturated when the pinned fraction at that level reaches a critical value above which the capillary bridges at that level may begin to interact destructively. The critical value may depend on the composition of the fluid in some embodiments. For embodiments including a compound fluid it may depend strongly on the miscibility of the components of the fluid as well as their molar fractions.

In general, for a single phase fluid the interaction between capillary bridges may result in a threshold for the normalized pinning ratio of about 1. In some embodiments, the threshold may be about 1.5. This effect may be due to coarsening effects between capillary bridges which are not segregated by an immiscible phase. However, for other embodiments with compound fluids, the peripheral contact length may be dramatically increased, and the capillary bridges cannot become coarser, which may result in greater pinning for larger number of hierarchical levels.

In certain embodiments, self-similarity may result in non-linear additive and destructive effects resulting in dramatically reduced pinning in the case of the lotus leaf and dramatically increased pinning for microstructures that induce a Wenzel-Cassie interface.

### Contact Angle Hysteresis

It should be understood that the difference between the advancing (OA) and receding (OR) contact angles on a microstructured surface may be termed hysteresis, and this value determines both the force required to initiate drop movement across the surface and the degree to which the drop may distort from its static state in order to move.

In some embodiments, contact angle hysteresis may be quantitatively equated to the force required for a liquid drop across a surface. Without contact angle hysteresis (where θ_{A}=θ_{R}), virtually no force is required to move the drop. It should be appreciated to one of skill in the art that advancing (θ_{A}) and receding (θ_{R}) contact angles may be one of the most meaningful contact angle values that can be measured and that contact angle hysteresis (CAH) may be a more meaningful measurement of shear pinning than any contact angle (CA) value alone.

As an example, one experimental method to be used in quantifying contact angle hysteresis is the sessile drop method as previously disclosed by Románszki, L., Mohos, M., Telegdi, J., Keresztes, Z., Nyikos, L. “A comparison of contact angle measurement results obtained on bare, treated, and coated alloy samples by both dynamic sessile drop and Wilhelmy method”, Periodica Polytechnica Chemical Engineering, 58(Supplement), pp. 53-59, 2014, For various experiments and data disclosed herein, this method was utilized.

In some embodiments, an interaction volume may translate on microstructured surfaces due to capillary bridges that may form during dewetting at the receding contact line. In some embodiments, a microstructured surface having a contact angle hysteresis greater than 5 degrees can exhibit anomalous fluid pinning due to capillary bridge formation. In other embodiments, a microstructured surface having a contact angle hysteresis in the range of 15 to 40 degrees may be preferred for microstructured devices of the present disclosure.

It should be appreciated that the forces involved in some of the embodiment disclosed herein may be mostly perpendicular to the plane of translation of one surface in relation to another. In certain embodiments, as the liquid interface translates, the advancing contact line may continually reform as the liquid-vapor interface spontaneously wets the microstructures.

These processes may generate some vertically oriented forces, which may be due to high contact angles. In some embodiments, the microstructure surface may retain liquid during receding events, which may cause contact line pinning. Microstructure pinning may also occur within the interaction volume. In some embodiments, that mechanism may be due to capillary bridge disruption and mixing of liquid phases.

In some embodiments of the present disclosure, the forces for rupturing capillary bridges may decrease the macroscopic receding contact angle preferentially, thus the pinning of capillary bridges may increase contact angle hysteresis.

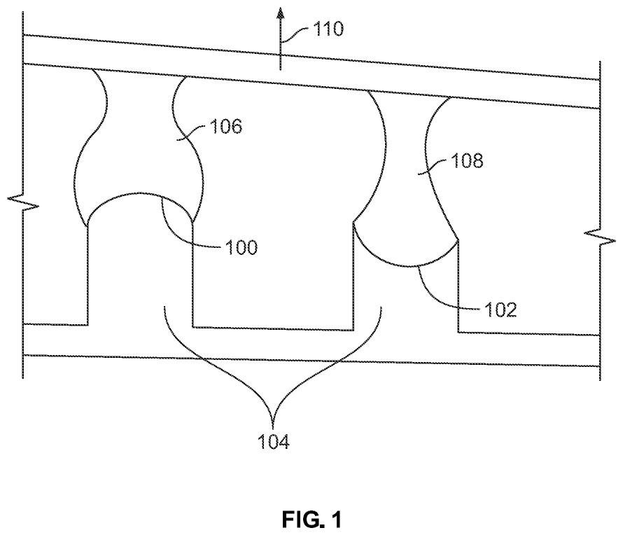

In certain embodiments, the surface curvature of a microfeature may play an important role in contact angle hysteresis. In some embodiments, the curvature or shape of one or more microfeatures may cause receding contact line pinning on surfaces that, from a chemical perspective, would be considered “hydrophobic.” Referring now to FIG. 1, in one embodiment, a concave curvature 102 of the microfeature may inhibit water repellency as compared to a convex curvature 100. FIG. 1 depicts two microstructures 104 of identical surface area and composition that may form capillary bridges 106, 108 respectively. The target surface may be subject to a normal force in the direction 110. In FIG. 1, capillary bridge 106 may be convex at the anchoring point of the microfeature and capillary bridge 108 may be concave at its anchoring point to the microfeature. The normal force 110 may act on the capillary bridge 106 which may cause the contact angle to be a lower value, resulting in the contact line to recede. The same normal force 110 may act on capillary bridge 108, which may increase the contact angle and may cause the contact line to advance.

In some embodiments, an important distinction may be made between an interaction volume having purified water as compared with fluid(s) mixed with nonionic components and saline environments, such as those commonly encountered in surgical procedures. Ionic compound fluids may likely be far more susceptible to pinning mechanisms due to surface morphology as well as to smooth chemically heterogeneous surfaces that establish the same Wenzel-Cassie partial wetting domains. In the chemically heterogeneous case, the sessile capillary bridge rupture may occur because of shear pinning of receding contact lines.

### Properties of Axial Asymmetric Capillary Bridges

In certain embodiments, the simplest axial asymmetric capillary bridge may be formed by confinement between a pinning hierarchical microstructure and a smooth target surface. The capillary bridge anchored on the microstructure may comprise anisotropic wetting properties. In such embodiments, the fluid may spread along the length of the microstructured strip but may be pinned by its width. This anisotropy may occur for both morphological and chemical pinning heterogeneity.

The visualization of the morphological evolution of a capillary bridge as it is stretched at constant volume can provide insight into its characteristics. In some embodiments, the Laplace pressure created by a capillary bridge may go from negative to positive as the height of the slit pore is increased. In embodiments with axially symmetric capillary bridges, this may not hold true. In comparison, for periodic microstructure arrays, this change is quite rare. Capillary bridges that approximate axially symmetric capillary bridges may be fluidically connected along one or more preferred directions. The directions may often be on the ground plane of the surface of the microstructure substrate or on the surface of the target substrate.

In some embodiments, the width of the capillary bridge at mid height may become larger than the width of the supporting strip with an increase in height such that the mean curvature of the bridge may change sign and go from negative (concave bridge) to positive (convex bridge).

Embodiments having microfeatures with an axial asymmetric wedge geometry, increasing the opening angle of the wedge may result in an increase in the mean curvature of the capillary bridge and may also change the sign from negative to positive curvature.

Since the Laplace pressure of the capillary bridge may have significant effects on stability, especially for compound liquid system, embodiments are disclosed based on the transition point, so that characteristics of the microfeatures can be made that are stably in either the convex or concave morphology. It should be understood that it may not always be the case that a low Laplace pressure capillary bridge yields the highest stability, especially when an adjacent capillary bridge of a different liquid may be behaving oppositely, such that the combined effect of both capillary bridge-types work together to destabilize both capillary bridges.

In certain embodiments, it may be beneficial to predict the transition from a negative to positive Laplace pressure capillary bridge as a function of the bridge height in a ridge-type geometry, assuming constant capillary bridge volume.

In some embodiments, assuming that the anchoring microstructure ridge may be longer than the length of the capillary bridge, the contact angle formed at the end of the ridge may be determined by the wetting angle of the first order microstructure. Also, the triple contact line on the length of the bridge may be characterized by the pinning angle. In this embodiment, the pinning angle may be a function of aspect ratio of the capillary bridge. In some embodiments, assuming that the mean curvature of the capillary bridge may be approximately constant over the axial length of the ridge, then the radius of curvature of the profile at the ends of the ridge may be inversely proportional to the wetting angle. The radius of curvature of the profile along the length of the ridge may be inversely proportional to the pinning angle.

Without going into mathematical detail, the balance between the aspect ratio of the capillary bridge and wetting properties of the first order microstructure may dictate the mean curvature or the pinning angle. But the aspect ratio of the capillary bridge may be proportional to the cosine of the wetting angle, consequently the curvature may change sign from negative to positive as the pinning angle becomes greater than π/2, which it may do in most cases.

It may also be understood that as the aspect ratio of the capillary bridge decreases by substituting ridges with larger width, the contribution of the wetting properties may become more important, and the capillary bridge may need a larger height for its curvature to change sign. This analysis also predicts that the transition between negative and positive mean curvature may occur at lower aspect ratios as the wetting angle of the first order microstructure increases.

### Pinning Angle vs Contact Angle

The term pinning angle may oftentimes be conflated with contact angle. It should be appreciated that contact angle is weakly correlated with pinning angle and contact angle hysteresis is likely a far more relevant parameter when creating microstructured devices of the present disclosure.

One aspect of the pinning angle as a defining quantity may be that it is a dynamical quantity that sensitively captures or correlates with the shape of the capillary bridge, which confirms that the stability of the capillary bridge may be the dominant factor in the pinning of a microstructured surface to a target surface. This may be meaningful when the capillary bridge is stabilized by a Wenzel-Cassie interface structure. This result is not appreciated in the prior art. The problem with using pinning angle as a definitive term in specifying a microstructured surface is that it depends strongly on the interface composition and geometry.

However, it should also be appreciated that as a design parameter, the pinning angle can be instructive. For example, in some embodiments, given the sensitivity of the pinning angle on capillary bridge height, the data disclosed herein is of particular interest when choosing the height of microstructures across hierarchical levels. The relative heights of microstructures can be important in capillary bridge stability. As a general design guidance principle, capillary strength may be understood to increase uniformly across the microstructured device when the anchoring surfaces for capillary bridges are closer to co-planar. Conversely, local areas of a microstructured device can be made more adhesive with respect to other local areas of the device using the insights disclosed herein.

It will be appreciated by those skilled in the art that the contact angle θ may be related to the pinning angle α by the following equation, where “H” is the height of the capillary bridge, “W” is the width of the capillary bridge at the point of contact with the microstructured surface, and “Rₙ” is the radius of the capillary bridge at its narrowest point.

$$cos α = cos θ - \frac{{HR}_{n}}{2 {( \frac{W}{2} - H \frac{1 - sin α}{2 cos α} )}^{2}}$$

A study was conducted to test the validity of this equation for microstructure surfaces and determine ranges of linearity which may serve as microstructured surface design guidance.

TABLE 1
Capillary Bridge Strength, Pinning Angle vs Capillary Bridge
Length (contact angle 145 degrees) Pattern 160, PLA

| Normalized Force | Capillary Bridge | Pinning Angle |
|---|---|---|
| (+/−10%) | Height H (microns) | (+/−2 deg.) |
| 0.73 | 250 | 76 |
| 0.54 | 500 | 132 |
| 0.31 | 750 | 166 |
| 0.26 | 1000 | 147 |
| 0.22 | 1200 | 131 |

TABLE 2
Capillary Bridge Strength, Pinning Angle vs Capillary Bridge
Length (contact angle 97 degrees) Pattern 160, PLA

| Normalized Force | Capillary Bridge | Pinning Angle |
|---|---|---|
| (+/−10%) | Height H (microns) | (+/−2 deg.) |
| 0.52 | 250 | 73 |
| 0.41 | 500 | 113 |
| 0.27 | 750 | 137 |
| 0.25 | 1000 | 147 |
| 0.24 | 1200 | 142 |

TABLE 3
Capillary Bridge Strength, Pinning Angle vs Capillary Bridge
Length (contact angle 67 degrees) Pattern 160, PLA

| Normalized Force | Capillary Bridge | Pinning Angle |
|---|---|---|
| (+/−10%) | Height H (microns) | (+/−2 deg.) |
| 0.44 | 250 | 69 |
| 0.39 | 500 | 94 |
| 0.35 | 750 | 116 |
| 0.31 | 1000 | 138 |
| 0.26 | 1200 | 140 |

Based on the data above, one can appreciate that the pinning angle as a function of capillary bridge height diverges with decreasing contact angle. Further, pinning angle decreases with increasing height, but the slope of pinning angle vs height decreases with decreasing contact angle.

The divergence of pinning angle with height is much greater than the divergence of pinning angle with contact angle, which means the first term of the equation provided above “cos θ” may be considered, in some embodiments, to be relatively unimportant. It may be apparent that the pinning angle is quite different from the contact angle.

It should also be appreciated that when the height “H” is small, the pinning angles are approximately the same regardless of the contact angle. In certain embodiments, the effect of contact angle on pinning angle may be greatest when the capillary force is about one half the maximum. In some embodiments, capillary force may decrease with decreasing contact angle. And in some embodiments, capillary force may decrease with increasing capillary bridge height.

### Capillary Bridge Force Hysteresis and Contact Angle Hysteresis

In some embodiments disclosed herein, capillary bridge force on some microstructured material may exhibit a high hysteresis. Thus, in some embodiments under oscillatory loading conditions, initial good liquid enhanced grip can exhibit significantly lower normal suction force for a fixed microstructure-target separation distance on the second time that separation distance is realized.

In embodiments where the capillary forces between a microstructured surface include moderate contact angle hysteresis and a target surface, both the advancing and receding contact angles may be less than 90° and the capillary bridge forces may be attractive for both approach and recession at small separations.

In embodiments with a microstructured surface having high contact angle hysteresis, upon approach the force may be repulsive at small separations, but the force may change to attractive for recession. This by itself may not be a bad feature in certain embodiments because it may provide a cushioning effect so that the microstructured surface and target surface do not mechanically abrade one another. Of course, it will be understood that this cushion effect can be overcome by sufficiently large normal forces.

The change from repulsive to attractive forces at small separations was found to be an indication of a range of advancing and receding contact angles for some particular embodiments. In certain embodiments, the approaching contact angle was from about 100° to about 130°, from about 110° to about 120°, or from about 115°, and the receding contact angle was from about 80° to about 100°, or from about 90°. This range may provide high capillary force hysteresis in some embodiments. Thus, capillary forces may be maximized for high contact angle hysteresis, but may only be stable for contact angles with a mean value above about 100°, or from about 100° to about 150°, or from about 100° to about 140°, or from about 110° to about 130°, or from about 110° to about 120°, or from about 110°.

For embodiments with low contact angle hysteresis (for example, less than about 5°), both the approach and recession data indicate repulsive forces may be exhibited at small separations. However, low contact hysteresis microstructured surfaces may also exhibit low capillary force hysteresis, which may be of marginal value in some embodiments since the capillary forces may be small, and repulsive.

The data as disclosed herein may provide those of skill in the art with an understanding that for some embodiments, the hysteresis of a capillary bridge force-displacement curve may be associated with the contact angle hysteresis of the bridge/substrate interface. This hysteresis may cause the specific force-separation relationship to be history-dependent. However, the force hysteresis for a given separation may be only significant when the advancing and receding contact angles are greater than, and less than about 90°, respectively.

### Capillary Force as a Function of Surface Separation and Contact Angle Hysteresis

The following data may provide some information with respect to capillary force hysteresis with respect to the difference in force compressing 100 microns vs lifting 100 microns from a tangent contact. It can be appreciated that capillary force hysteresis may increase for increasing contact angle hysteresis based on some embodiments herein. Capillary force hysteresis may be viewed as a stiffness with regard to the difference in compression and lift. In certain embodiments, high capillary force hysteresis may indicate good adhesive force and resistance to mechanical contact between the microstructured surface and the target surface. Additionally, based on the data below, for some embodiments, suck down force may decrease with increasing separation (i.e., increased positive displacement). Further, compressive force may increase with compression (i.e., increased negative displacement). It may also be appreciated that for some embodiments, suck down force may increase with increased contact angle hysteresis across a large variety of separation distances. And, compressive force may increase moderately in some embodiments for increased contact angle hysteresis over certain separation distances.

In the following tables, a negative vertical force may indicate suck down, and a negative displacement may indicate compression of the fluid droplet.

TABLE 4
Low Water Contact Angle Hysteresis, RTV, 2.7 +/− 0.3 degrees

| Displacement (microns) | Vertical Force (mg) |
|---|---|
| −800 | +44 +/− 8 |
| −600 | +25 +/− 5 |
| −400 | +18 +/− 7 |
| −200 | +8 +/− 7 |
| −100 | +5 +/− 4 |
| Capillary force hysteresis | 16 |
| +100 | −11 +/− 8 |
| +200 | −7 +/− 5 |
| +400 | −5 +/− 3 |
| +600 | −1 +/− 1 |
| +800 | released |

TABLE 5
Medium Water Contact Angle Hysteresis, PLA
Pattern 86,13 +/− 1.1 degrees

| Displacement (microns) | Vertical Force (mg) |
|---|---|
| −800 | +66 +/− 21 |
| −600 | +51 +/− 16 |
| −400 | +32 +/− 13 |
| −200 | +15 +/− 8 |
| −100 | +10 +/− 5 |
| Capillary force hysteresis | 102 |
| +100 | −92 +/− 19 |
| +200 | −54 +/− 28 |
| +400 | −31 +/− 14 |
| +600 | −17 +/− 5 |
| +800 | released |

TABLE 6
High Water Contact Angle Hysteresis, PLA Pattern
160 CP, 42 +/− 1.9 degrees

| Displacement (microns) | Vertical Force (mg) |
|---|---|
| −800 | +78 +/− 21 |
| −600 | +65 +/− 16 |
| −400 | +52 +/− 13 |
| −200 | +41 +/− 8 |
| −100 | +27 +/− 5 |
| Capillary force hysteresis | 150 |
| +100 | −124 +/− 31 |
| +200 | −91 +/− 29 |
| +400 | −74 +/− 15 |
| +600 | −46 +/− 9 |
| +800 | −37 +/− 8 |

### Optimizing the Interface Cushion

In some embodiments, of which may include medical implant applications, an implant may be required to be adhesive to a wet surface but not damage that surface with abrasion from the microstructure pattern. As disclosed herein, where Wenzel-Cassie constrained capillary bridges exist between the microstructured surface and the target surface, the microstructured surface may not actually touch the living tissue under minimal loading conditions.

In certain embodiments, fluid may be trapped between the microstructured surface and the tissue, and the capillary bridges may be constrained so their fluids may not readily leave the interaction volume. In these embodiments, the capillary bridges may be considered to act like shock absorbers, allowing for displacement of fluid without actual net fluid loss. The small amount of fluid displacement that may occur in these embodiments may occur with the less pinned fluid fraction being sucked back into the interaction volume by the repulsive force of the constrained capillary bridges. Additionally, trapped gas may give an additional margin of compliance in the embodiments.

The data provided herein may reveal, unsurprisingly, that surface patterning may play a role in the effective stiffness of a capillary bridge within some embodiments. In certain embodiments, whenever the sum of the contact angles is less than about 150 degrees, the spring constant may be about zero, or may be at least minimal.

In certain embodiments, the spring constant may get softer with increasing volume, and may peak around a mean contact angle of about 80° to about 100°, or about 90°, and may get slightly softer as the mean contact angle increases. The fact that the spring constant may be maximally stiff near where the spring constant goes to zero may indicate a transitional mechanism (breaking of the capillary bridges) from constrained capillary bridges to fluid displacement, which may also explain the large capillary force hysteresis in this same range of mean contact angles. However, the maximum value of the spring constant and the rate at which it decreases may depend on the properties of the two plates in certain embodiments. For example, it may be possible to devise a configuration where the spring constant is relatively soft for a large range of parameters.

### Capillary Bridge Stiffness

In some embodiments, maximum surface separation before capillary bridge failure as a function of contact angle may provide an indication of capillary bridge robustness. Maximum normalized volume vs normalized surface separation as a function of contact angle hysteresis may provide an additional measure of capillary bridge robustness. Normalized Spring Constant (stiffness, k) as a function of contact angle and contact angle hysteresis can provide a of some embodiments regarding contact angle, contact angle hysteresis, robustness of the capillary bridge, and stiffness of the capillary bridge.

Based on the data presented below, Maximum Surface Separation Before Capillary Bridge Failure (water) Vs Contact Angle indicates that the higher the contact angle the larger the surface separation (i.e., length of the capillary bridge right before breaking). Additionally, Maximum Normalized Volume Vs Normalized Surface Separation (low contact angle hysteresis) indicates that increasing capillary bridge length may result from increasing drop volume. For embodiments with high contact angle hysteresis, the same trend was observed, but the high contact angle hysteresis showed much longer capillary length as a function of volume compared to low contact angle hysteresis. This study showed increasing contact angle hysteresis may create a capillary bridge that may be more robust, which may lead to being able to support more water in the capillary bridge and creating longer capillary bridges.

Normalized Spring Constant (stiffness, k) as a Function of Contact Angle indicates certain embodiments with increased stiffness (spring constant) with lower contact angle. Combining these embodiments with shorter capillary bridge length for lower contact angle, one may understand that increasing stiffness of the capillary bridge may generally reduce the maximum allowed separation of the surfaces before capillary bridge failure. On the other hand, comparing low contact angle hysteresis to high contact angle hysteresis embodiments, the higher contact angle hysteresis may increase the capillary bridge length as a whole, suggesting increased contact angle hysteresis may increase capillary bridge robustness.

TABLE 7
Maximum Surface Separation Before Capillary Bridge Failure (water)
Vs Contact Angle

| Contact Angle (degrees +/- 1 degree) | Normalized Surface Separation (+/- 10%) ${L ( \frac{4 V}{π} )}^{- \frac{1}{3}}$ |
|---|---|
| 161 | 1.10 |
| 153 | 1.04 |
| 134 | 0.83 |
| 119 | 0.65 |
| 103 | 0.40 |

TABLE 8
Maximum Normalized Volume Vs Normalized Surface
Separation (Contact angle hysteresis 3°)

| Normalized Surface Separation (+/- < 5%) $\frac{L}{R}$ | Normalized Volume (+/- < 5%) $\frac{V}{{R}^{3}}$ |
|---|---|
| 0.45 | 2.1 |
| 1.03 | 3.4 |
| 1.55 | 6.2 |
| 2.24 | 10.9 |
| 2.78 | 20.2 |
| 3.40 | 37.1 |

TABLE 9
Maximum Normalized Volume Vs Normalized Surface
Separation (Contact angle hysteresis 42°)

| Normalized Surface Separation (+/- < 5%) $\frac{L}{R}$ | Normalized Volume (+/- < 5%) $\frac{V}{{R}^{3}}$ |
|---|---|
| 0.40 | 3.3 |
| 0.98 | 5.0 |
| 1.61 | 9.9 |
| 2.17 | 15.6 |
| 2.9 | 32.7 |
| 3.37 | 59.9 |

TABLE 10
Normalized Spring Constant (stiffness, k) as a Function
of Contact Angle (Contact Hysteresis 2°-5°)

| K (+/−10%) | Contact Angle (+/−<5%) |
|---|---|
| 0.2 | 148 |
| 0.6 | 133 |
| 1.2 | 111 |
| 1.8 | 102 |
| 6.5 | 94 |
| 0.2 | 148 |

TABLE 11
Normalized Spring Constant (stiffness, k) as a Function
of Contact Angle (Contact Hysteresis 31°-39°)

| K (+/−10%) | Contact Angle (+/−<5%) |
|---|---|
| 0.7 | 151 |
| 1.3 | 131 |
| 3.2 | 119 |
| 9.2 | 108 |

### Chemical Vs Morphological Constraint of Wenzel-Cassie Capillary Bridges

In some embodiments, the microstructure pattern may be based on structural/morphological characteristics, may be based on material characteristics, or may be based on chemical characteristics, or a combination thereof. In certain embodiments, chemical Wenzel-Cassie constrained capillary bridges may offer benefits that morphologically microstructured surfaces do not (both are considered microstructured surfaces). Embodiments comprising at least a portion of the microstructure surface that is chemically-based, the capillary bridges may be constrained by electric fields. Embodiments comprising at least a portion of the microstructure surface that is morphologically-based, the capillary bridges may be constrained by both field effects and physical barriers, e.g., the edge of a microstructure.

Embodiments comprising at least a portion of a chemically structured surface consisting of oleophilic and oleophobic surface domains may be characterized by small and large contact angles, which may initiate the Wenzel-Cassie structure required for capillary bridge formation and constraint. Embodiments comprising such a surface may create morphological wetting transitions at which the shape of the wetting layer may change in a characteristic and typically abrupt manner that is generally not possible for morphological microstructure surfaces. Embodiments comprising chemically structured microstructured surfaces may also include the added flexibility of responding in different ways to surfaces bearing liquid layers of different thicknesses, or surfaces that exude liquid.

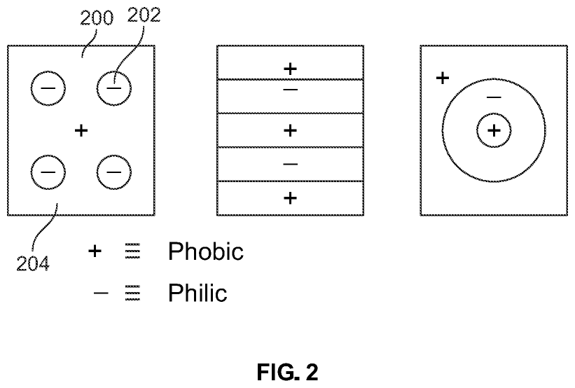

Referring now to FIG. 2, a microstructure pattern 200 may comprise circular domains 202. In one embodiment, the circular domains 202 may have approximately the same diameter. In a particular embodiment, the circular domains 202 may be oleophilic, and the substrate surface 204 may be oleophobic. In some embodiments having small volume fluid, the wetting layer consists of identical droplets centered on the circular domains 202. In some embodiment, the circular domains 202 may all have the same, or similar, shapes. In one embodiment, the circular domains may comprise a small spherical cap.

The contact angle of this cap may be determined by the subvolume of each droplet since the usual Young equation may not be valid if the contact line is pinned to the domain boundaries. As the volume of liquid increases on the target surface, a certain volume may be reached at which the wetting layer undergoes a transition to a droplet pattern with one large drop and N−1 small droplets, where N is the total number of domains 202. The large and the small droplets may have the same mean curvature. Increasing the volume of liquid on the target surface may result in one of the small droplets combining with the large drop.

In certain embodiments, the fluid may transition from a hemisphere to a complete sphere, with its center shifted over the oleophobic domain 204. This may result in a completely different capillary bridge structure. If a target surface was in place, the capillary bridge may transition from a cylinder bridging the layers to a bifurcate “pants” capillary bridge. For larger and larger volumes, the large drop becomes increasingly larger and the small droplets become decreasingly smaller, which eventually may lead to forming larger regions of bifurcation. Thus, the whole-surface capillary bridge structure may increase the capillary force (liquid enhanced grip) in response to the amount of liquid on the target surface.

It should be noted that, in some embodiments, the resistance to shear translation due to chemical microstructure may be less than morphological microstructured surfaces of the same dimension. In comparison, for an embodiment having at least a portion of a morphological microstructured surface, the drops on the oleophilic domains 202 may saturate at a certain size, and may not generate the bifurcating capillary bridge structure observed for a chemically microstructured surface. This may be due to the physical barrier separating droplets. At some threshold volume of water on the target surface, the whole surface may transition to a pillar-to-pillar capillary bridge structure, and the gradual bifurcation in capillary bridge structure may not occur. Consequently, the resistance to shear translation may not increase as the target surface gets wetter but may undergo an abrupt change in capillary force at some threshold water volume. Since the capillary bridge may be much longer relative to the microstructure surface substrate, due to the raised pillar, the capillary bridges may be more prone to destabilization unless quantities of an oleophobic fluid is added to the target surface.

Previously, a microstructure surface comprising a morphological ring structure has been of particular interest, but difficult to construct. In particular, it has been difficult to construct such a microstructure pattern where the circular region inside the ring has the same contact angle as the region immediately surrounding the ring. Morphological transitions from a channel with uniform cross-section to a channel with a single bulge can occur for ring-shaped surface domains. The appearance of the bulge breaks the rotational symmetry of the ring channel which implies that the position of the bulge is degenerate. Therefore, angular displacements of this bulge do not cost any free energy. Consequently, such a microstructure surface would be adaptable to a target surface where the philic and phobic domains are randomly distributed.

### Designs for Lubricant Infused Surfaces

A surface that contains lubricant as part of its structure is referred to herein as a lubricant infused surface (“LIS”). Many lubricant infused surfaces may have a structural relationship with the lubricant that coats them, which may extend down into the infused surface. Relevant to this disclosure, some lubricant infused surfaces may continuously exude the lubricant, as in living tissue, where the lymph system continuously exudes lymphatic fluid comprised mostly of proteins, salts, glucose, fats, and water. In this case, the fats perform the lubricating function. Other lubricant infused surfaces are also known and may also have relevance to embodiments disclosed herein.

The interaction volume involving a lubricant infused surface may differ from a typical compound liquid interaction volume in that the at least one component is lubricating for all surface textures, and the molar fraction of the lubricant maybe less than about 10% of the total volume. Unlike the typical compound fluid, competing capillary structures are typically not formed. Rather, the lubricant may form a compound capillary bridge comprising typically a hydrophilic core that may be lightly, and in some embodiments, completely encased in a coating of the lubricant, which may typically be more hydrophobic.

Nevertheless, this coating may act in some instances as a confinement mechanism for the hydrophilic capillary bridge. In some embodiments, this mechanism may be different from mutually stabilized capillary bridges disclosed elsewhere herein. Nevertheless, both can be considered Wenzel-Cassie interfaces, since there is a clear phase domain between the capillary bridge and its coating.

The prior art literature contains studies of self-cleaning lubricant infused systems, both living and nonliving. This disclosure provides that such systems can be adhesive, especially in the normal direction, which is generally overlooked because the concern is that the systems have low resistance to shear translation. However, by adding a microstructured layer, the suctional normal force may translate to strong adhesion in the shear direction with respect to the target lubricant infused surface.

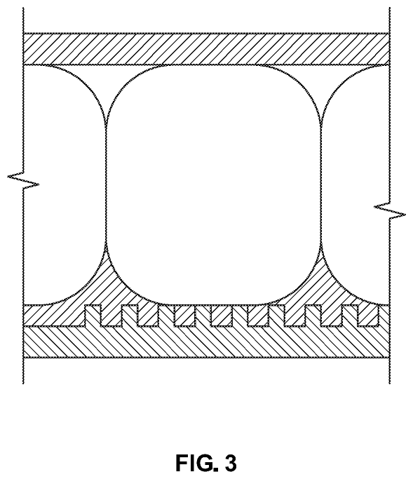

It should be appreciated by those skilled in the art that this disclosure provide a surprisingly large number of stabilizing modes. Referring now to FIG. 3, regarding capillary adhesion on LIS, a pure liquid interface (the second component comes from the LIS) is depicted sandwiched between a LIS and a microstructured device. The physical quantities of interest are the Neumann and wetting contact angles. The Neumann contact angle differs from the rigid limit (Young), and is the soft limit (Neumann), applicable when the length scale defined by the ratio of surface tension to elastic modulus reaches a few molecular sizes. The Neumann contact angles are relevant since the LIS is a hybrid liquid-solid phase.

The fact that capillary bridges on LIS involve two liquid components, instead of just one, leads to several interesting phenomena. Firstly, two-component liquid bridges can exhibit a wider range of interfacial topologies unique to LIS system. Morphological transitions may readily occur when compressing and stretching the capillary bridges. Thus, the capillary bridges may have a number of low energy states available to them.

In some embodiments, one of the characteristic capillary bridge topologies may involve the formation of lubricant ridges that combine with the capillary bridges at the point of contact between the liquid interface and the LIS. The lubricant ridges can self-organize, especially when proteins may be present, which may lead to a self-assembled microstructure on the target surface induced by the microstructure on the device. These lubricant ridges may be stabilizing to the formed capillary bridge. Both the size and shape of the lubricant ridge may play an important role. Numerical calculations suggest these lubricant ridges, even when they are quite mobile, can easily double the capillary pinning force.

One consideration for certain embodiments is that the lubricant may be supplied at a sufficiently slow rate. This constant flow of the lubricant over the capillary bridge can be important in some embodiments. It should be noted that the lubricant layer can vary in size, and may be only a few nanometers in thickness, or can be thicker on the order of microns. The lubricant exchange between the ridge and surrounding substrate can occur on a rather slow timescale due to the strong viscous dissipation in the thin lubricant layer. This may allow the pressure ensemble for the lubricant to be parameterized by the pressure jump at the lubricant-gas interface. This term in the free energy may represent the energy cost for drawing additional lubricant. It is this cost that may generate a capillary-like suck down on the LIS. In some embodiments, the lubricant layer may form a tube around the capillary bridge, which may create tension between the anchor point of the microstructured device and the capillary driven porosity of the LIS. The capillary tension may project into the LIS. This force may be in addition to the force generated by the capillary bridge, which is more superficial.

In certain embodiments, the lubricant may only partially wet the target surface. The substrate of the target surface may be effectively a composite of the underlying rough solid surface and the imbibed lubricant of the LIS. Rather than calculate the details of the composite surface, an effective average surface tension may instead be used, derived from the fraction of the projected solid area exposed to the drop or gas phase. One may also derive an effective contact angle between phases on the composite solid-lubricant substrate. The complete wetting case may give essentially the same results provided the lubricant thickness on the microstructured device is small compared to the size of both the liquid interface and the lubricant ridge.

In certain embodiments, one defining characteristic of the LIS system is that the drop-gas interface may not come in contact with the microstructure surface, due to the ubiquitous presence of a lubricant ridge. At the top of this lubricant ridge, there may be a triple contact line where the liquid-gas interface meets the lubricant-gas and lubricant-liquid interfaces. The three Neumann angles may be related to the interfacial tensions through a well-known equation.

In some embodiments, capillary bridge stability may steadily rise up to an apparent contact angle of approximately 99° and may remain approximately (within +/−5%) constant out to 140°. Surprisingly, shortening the capillary bridge below a normalized value of 0.9 s (wherein “s” is the characteristic length scale of the interaction volume) may result in unstable bridges below approximately apparent contact angle 90°. For these smaller contact angle embodiments, the capillary bridge may be lengthened to get stable bridges. When the capillary bridge length is longer than approximately 2.5 s, there may be no stable capillary bridges within the embodiment.

In some embodiments, envelopment instability may occur for high lubricant Neumann angles. Luckily, this may not be a problem for embodiments wherein the lubricant is a lipid. In general, the capillary bridge stability may increase for lower surface tension lubricants.

### Capillary Bridge Strength Vs Lubricant Neumann Angle

For embodiments having a compound liquid interface, the Neumann angle of the lubricant (phobic) phase can significantly affect the stability of interlocking capillary bridges in a microstructured liquid interface. It may be understood that increasing Neumann angle and having higher surface tension may result in weaker capillary bridges. Thus, lubricants that are less polar, and more hydrophobic, and more lubricating may be understood to strengthen the capillary bridge.

In the tables below, compound liquids with a small fraction (10%) of the lubricant phase are reviewed for different Neumann angle lubricants. This allows us to mimic the composition of lubricant infused target surfaces such as living tissue.

TABLE 12
Capillary Bridge Strength vs Capillary Bridge Length (lubricant
Neumann angle, 11 degrees) Pattern 160, PLA

| Normalized Force | Normalized Surface Separation (+/- 10%) ${L ( \frac{4 V}{π} )}^{- \frac{1}{3}}$ |
|---|---|
| 0.50-0.45 | 1.0 |
| 0.47-0.42 | 1.5 |
| 0.43-0.39 | 2.0 |
| 0.41-0.34 | 2.5 |

TABLE 13
Capillary Bridge Strength vs Capillary Bridge Length (lubricant
Neumann angle, 21 degrees) Pattern 160, PLA

| Normalized Force | Normalized Surface Separation (+/- 10%) ${L ( \frac{4 V}{π} )}^{- \frac{1}{3}}$ |
|---|---|
| 0.48-0.41 | 1.0 |
| 0.43-0.38 | 1.5 |
| 0.40-0.36 | 2.0 |
| 0.35-0.32 | 2.5 |

TABLE 14
Capillary Bridge Strength vs Capillary Bridge Length (lubricant
Neumann angle, 33 degrees) Pattern 160, PLA

| Normalized Force | Normalized Surface Separation (+/- 10%) ${L ( \frac{4 V}{π} )}^{- \frac{1}{3}}$ |
|---|---|
| 0.40-0.36 | 1.0 |
| 0.37-0.32 | 1.5 |
| 0.34-0.29 | 2.0 |
| 0.30-0.24 | 2.5 |

### Use of a Varying Height (Sinusoidal) Substrate

Microstructures may be understood to be generally discrete structures, in the sense that they have well defined edges defining their dimensions. Certain embodiments disclosed herein may use a continuously varying microstructures, such as a sinusoid, which can be thought of as one level of microstructure pattern. In certain embodiments, such structures can be useful in establishing stable capillary bridges with a surface of varying topology. In some embodiments employing a sinusoid microstructure pattern, this may allow for varying the surface of the substrate height relative to the target surface. In at least some embodiments, the microstructures may come sufficiently close to the target surface to establish stable capillary bridges. In addition, continuously varying microstructures can be usefully employed in catching Schallamach waves or eigen wrinkles that may be induced when the microstructure begins to translate relative to the target surface.

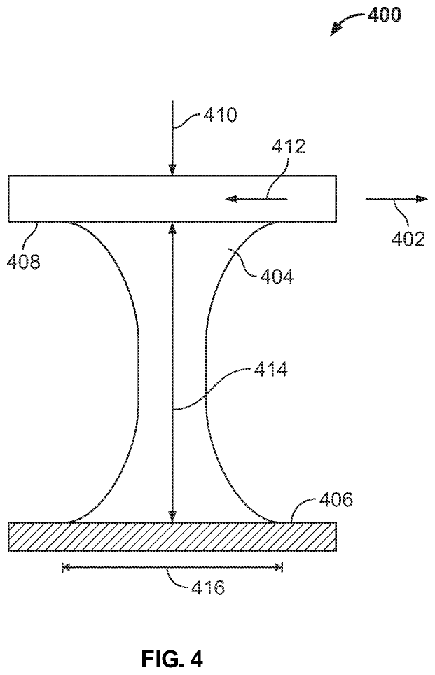

In addition to the above considerations, embodiments utilizing continuously varying microstructures can also be employed even when the target surface may be relatively flat. Referring now to FIG. 4, a capillary bridge interface 400 is depicted that includes a shift force in direction 402 that may cause the shear translation of a capillary bridge 404 pinned to fixed points on the microstructured surface 406 and target surface 408. A normal force 410 (countering lift) indicates a normal restoring force and indicates a shear force 412 (counters lateral translation). FIG. 4 further depicts the length of the capillary bridge 414 and the diameter 416 at the position where the mushroom profile pillar contacts the microstructured surface. It can be appreciated that the length of the capillary bridge 414 divided by diameter 416 may be the aspect ratio of the capillary bridge. In embodiments where the length of the capillary bridge is increased the normal restorative force 410 may decrease, but very gradually. When the pinning points of the capillary bridge is shifted in shear, the restorative force 412 increases significantly.

Thus, in some embodiments there may be an advantage in increasing the aspect ratio of the capillary bridge in order to localize the microstructure surface with respect to the target surface, in shear. Therefore, in certain embodiments one might employ “standoffs,” relatively sparse pillars intended just to maintain a certain distance from the pinning surface of the microstructure and the target surface, in order to counter the normal force 410 (also may be referred to as the suck down force). Other embodiments may include the microstructures on the periphery to be taller in order to make the edges be in maximal contact with the target surface, while the interior microstructure may be of shorter height in order to maximize localization against lateral translation.

However, one advantage of embodiments can be found when a continuously varying microstructure is employed on a microstructure surface that may ensure some microstructures maximize suck down while others maximize resistance to lateral displacement. In certain embodiments employing such microstructures with a sinusoidally varying background, these patterns may outperform a microstructure surface where the pinning surfaces of the microstructures lie in a plane.

### Designs for Mutually Reinforcing Capillary Bridge Structures

The stability of capillary bridge structures can be optimized by a mutual confinement scheme between different compound liquid phases in some embodiments. One may employ embodiments with a two-level microstructure for optimizing the capillary stability for a two-component compound liquid interaction volume. These capillary bridges may be stabilized against vertical displacement, lateral displacement, and/or frequency response. One goal of topology capillary bridge stability is to find the optimum pinning distribution of a microstructure for the two phase-type capillary bridges. Generally, optimization algorithms optimize for capillary bridge stability at the different hierarchical levels separately. Here, the aim is to obtain a synergistic interaction between two micro scales of pinning dynamics.

If one employs embodiments with a multiscale system with known boundary conditions and external force and frequency ranges, the optimization objective is to minimize the amplitude of the destabilization response to external factors at a specific point(s) within the interaction volume of the microstructure. A concurrent topology optimization scheme is developed to find the topologies of both the macro structure and the micro structure so that the optimization objective is achieved.

Static as well as harmonic loads should be considered when using these microstructure embodiments. When loads are acting in the system, two distinct situations may be considered: (1) when the external force is acting under just one determined frequency or statically; (2) when the applied load can oscillate in a frequency range. For the first situation, the sensitivity numbers can be calculated directly. For the second situation, a variational approach may be required. The basic idea is to define a generic stable pinning geometry under static conditions, and then study the individual capillary bridge stabilities under different aspect ratio perturbations. See Example 4 provided herein.

### Interlocking Capillary Bridge Study

In some embodiments, capillary bridges between juxtaposed Wenzel and Cassie domains for the same fluid may form capillary bridges with complementary surface curvatures. In such embodiments, in addition to stabilizing and constraining adjacent capillary bridges by their differences in surface energy (immiscibility condition), adjacent capillary bridges of different surface energy may actually interlock, since hydrophilic capillary bridges will tend to have a surface curvature of different sign than hydrophobic capillary bridges. Thus, embodiments which utilize convex capillary bridges may lock with concave capillary bridges, and that this is a unique rheology specific to microstructured surfaces that form Wenzel-Cassie interfaces.

TABLE 15
Capillary Bridge Surface Curvature Vs Normalize Capillary Bridge
Length For Smooth Surface (Contact Angle 13 degrees)
(contact angle hysteresis < 5 degrees)

| Surface Curvature | Normalized Surface Separation (+/- 10%) ${L ( \frac{4 V}{π} )}^{- \frac{1}{3}}$ |
|---|---|
| +0.92 | 0.5 |
| +0.11 | 1 |
| +0.08 | 1.5 |
| -0.17 | 2 |
| -0.37 | 2.5 |

TABLE 16
Capillary Bridge Surface Curvature Vs Normalize Capillary Bridge
Length For Smooth Surface (Contact Angle 42 degrees)
(contact angle hysteresis < 5 degrees)

| Surface Curvature | Normalized Surface Separation (+/- 10%) ${L ( \frac{4 V}{π} )}^{- \frac{1}{3}}$ |
|---|---|
| +0.76 | 0.5 |
| -0.07 | 1 |
| -0.27 | 1.5 |
| -0.30 | 2 |
| -0.29 | 2.5 |

TABLE 17
Capillary Bridge Surface Curvature Vs Normalize Capillary Bridge
Length For Smooth Surface (Contact Angle 73 degrees)
(contact angle hysteresis < 5 degrees)

| Surface Curvature | Normalized Surface Separation (+/- 10%) ${L ( \frac{4 V}{π} )}^{- \frac{1}{3}}$ |
|---|---|
| +0.21 | 0.5 |
| -0.64 | 1 |
| -0.75 | 1.5 |
| -0.71 | 2 |
| -0.64 | 2.5 |

TABLE 18
Capillary Bridge Surface Curvature Vs Normalize Capillary Bridge
Length For Smooth Surface (Contact Angle 103 degrees)
(contact angle hysteresis < 5 degrees)

| Surface Curvature | Normalized Surface Separation (+/- 10%) ${L ( \frac{4 V}{π} )}^{- \frac{1}{3}}$ |
|---|---|
| -0.27 | 0.5 |
| -0.51 | 1 |
| -0.57 | 1.5 |
| -0.48 | 2 |
| -0.39 | 2.5 |

TABLE 19
Capillary Bridge Surface Curvature Vs Normalize Capillary Bridge
Length For Smooth Surface (Contact Angle 103 degrees)
(contact angle hysteresis, 38 degrees)

| Surface Curvature | Normalized Surface Separation (+/- 10%) ${L ( \frac{4 V}{π} )}^{- \frac{1}{3}}$ |
|---|---|
| -0.31 | 0.5 |
| -0.67 | 1 |
| -0.80 | 1.5 |
| -0.92 | 2 |
| -0.95 | 2.5 |

It can be appreciated that the smaller the contact angle, the larger the range when the surface curvature of the capillary bridge is positive. For embodiments including contact angles greater than about 80° to 100°, or about 90°, degrees the surface curvature may be positive. This suggest that for micro-domains of these disclosed microstructured surfaces, the micro-domains that are liqui-phobic (high contact angle) to the interface liquid may have a negative surface curvature, i.e., will be less adherent, whereas micro-domains with liqui-philic (low contact angle) to the interface liquid may have less negative to positive. For embodiments having a contact angle from about 10° to 20°, or from about 5° to 15°, or from about less than 15° contact angle, even when the normalized separation is greater than 1 the curvature may still be positive. This positive curvature under stretching may represent gravitational sagging combined with a high level of adherence.

Considering the above data, comparing the same contact angle with high and low contact angle hysteresis, the increased stiffness of high contact angle hysteresis capillary bridges may cause the necking of the capillary bridge to occur much earlier in the separation. This may be indicative of higher capillary force. This may further suggest there may be a benefit for certain embodiments where a mixed hydrophilic and hydrophobic domain (induced chemically or by varying the pitch) on one microstructure scale level could enhance capillary bridge interlocking by increasing the negative curvature of these capillary bridges. A similar effect could also be derived by having more levels, where capillary bridges may form on pairs of levels. There may also be advantages of these embodiments having mixed morphological microstructures with chemical microstructures.

### Effect of Fluid Density and Surface Tension on Capillary Bridge Formation

Applying the Young-Dupre equation, one can calculate the threshold for pinning as a function of tilt angle and contact angle hysteresis. In order to determine the capillary bridge stability, one has to assume a typical Eotvos number. In fluid dynamics the Eotvos number is a dimensionless number measuring the importance of gravitational forces compared to surface tension forces and may be used to characterize the shape of capillary bridges moving in a surrounding fluid, i.e., under lateral translation. In the tables provided below, the Eotvos number was set to 2.25 and the angle of inclination of the microstructured surface with respect to gravity was varied between 0 and 50 degrees. The fluid may be assumed to be water.

The reported results vary dramatically when the fluid density and surface tension are varied. Using equations relating contact angle to these parameters were used to obtain the results given below. Thus, when one understands the following data, one can employ an embodiment of a microstructured surface for a fluid with given density and surface tension which maintains stable capillary bridges under a shear force. In particular, one can employ these embodiments by making sure the contact angle hysteresis exceeds the threshold value for a given shear force or tilt angle.

The fluid density vs surface tension may be adjusted in a compound water-based system and applied in fixed size drop to a microstructured surface (160 CP, PLA) inclined at 60 degrees in order to determine the pinning threshold. This provides microstructure surfaces with suitable capillary force to establish stable fluid pinning for target surfaces comprising fluids within a known range of surface tension and density.

Methods

Density of water was decreased with alcohol, increased with glycerol and nonionic solutes. The surface tension of water was decreased with surfactant and increased with sodium chloride. Accordingly, the pinning threshold for Pattern 160CP casted from PLA was used as the microstructured test article.

TABLE 20
Pinning as a Function of Surface Tension
and Fluid Density (160 CP, PLA)

| Surface tension mN m⁻¹ | Fluid Density kg m⁻³ | Status |
|---|---|---|
| 21 | 732 | unpinned |
| 37 | 756 | pinned |
| 45 | 974 | pinned |
| 70 | 1000 | pinned |
| 47 | 1057 | unpinned |
| 56 | 1243 | unpinned |
| 65 | 1364 | pinned |
| 67 | 1478 | unpinned |
| 82 | 1729 | pinned |
| 77 | 1817 | unpinned |
| 91 | 1929 | pinned |

Based on the foregoing data, certain embodiments produce a pinning threshold that follows a linear relationship between surface tension and fluid density for a fixed microstructure surface pattern. As the water density increases, the surface density may increase proportionally to maintain a pinned state. In certain embodiments, water may be near the maximum for liquid surface tension. This fact puts a limit on fluid density for pinning, at least for the microstructure tested. This limit is approximately 1.75 times the density of water.

### Reentrant Microstructure Profiles for Stable Capillary Bridges

A simple polygon that is not convex may be referred to herein as “reentrant.” A concave polygon may have at least one reflex interior angle—that is, an angle with a measure that is between 180 degrees and 360 degrees. A microstructure may be reentrant if it has a two-dimensional cross section that is a reentrant polygon. Doubly reentrant, as used herein, may be understood to mean a microstructure with a two-dimensional cross section possessing two reflex interior angles.

The relationship between the intrinsic contact angle and the wetting contact angle for the wetting regime, and the non-wetting contact angle are compared for straight sided pillar (a) and reentrant pillars (b). The Wenzel and Cassie-Baxter regimes may be the same for both pillars, but the reentrant pillar may include an omniphobic regime which may be associated with a stable capillary bridge formation regime. No such regime exists in the straight pillar embodiment. Thus, in embodiments with reentrant microstructures, there may be a more stable capillary bridge structure, both inside the interaction volume and between the microstructures and the target surface.

For embodiments with reentrant microstructures, the intrinsic contact angle may be relatively small, i.e., the preferred domain may be on the more hydrophilic side of the omniphobic domain and on the more hydrophobic side of the superhydrophilic domain. This is generally where the contact angle hysteresis may be greatest for omniphobic microstructures. The stability of the capillary bridges in this domain may allow for the maintaining of partial wetting configuration via a Wenzel-Cassie type wetting scenario (sometimes called nanoCassie wetting).

### Minimization of Torsion Induced Capillary Bridge Instability

Torsion occurs when the pinning surfaces are asymmetric or have a preferred direction regarding a translational mode. In most embodiments and applications of the devices disclosed herein, the microscopic details of the target surface may be generally unknown when designing the microstructured surface. Generally, the target surface may be randomly asymmetrical, and therefore the application of an embodiment to these types of target surfaces may include the assumption that at least one end of the capillary bridge is pinned rotationally.

When the other end of a capillary bridge is also pinned rotationally, that torsion induced stress can develop in the bridge. In embodiments where the pinning surface of the microstructure may be geometrically asymmetric, then the anchor point of the capillary bridge may be rotationally pinned. In some embodiments, this pinning may be on short time scales.

In some embodiments, this may include an example such as bridge joining crossed fibers. However, in these embodiments, adding morphological microstructure to an anchoring surface can also induce rotational pinning. Thus, one embodiment may include the application of a microstructure to change the surface energy of a pinning surface. In other embodiments, the addition of a uniform chemical coating may be used. In embodiments having a chemical coating, viscous drag can induce torsion. However, in many embodiments, this may generally occur on short time scales, though not always depending on the microstructure pattern and/or chemical composition, or in view of other factors. In some embodiments, the chemical coating may be preferred, but entails additional manufacturing steps beyond a simple molding process.

The dynamics of viscoelastic liquid bridges under torsion may depend on the complex interaction between inertial, elastic, capillary, and gravitational stresses, which involve four dimensionless parameters: the Reynolds number, the Weissenberg number, the capillary number, and the Bond number. Without going into the mathematical details, shear forces may localize on the thinnest part of the capillary bridge when torsion is present, and the liquid bridge is concave. In some embodiments, the torsion increases the concavity of the capillary bridge.

However, in embodiments where the fluid is viscoelastic, viscoelastic capillary bridges under torsion can generate stresses normal to the axis which may compensate for the torsional narrowing. In some embodiments, there can also be a development of a localized region of positive first-normal stress difference and negative region of second-normal stress difference. This may localize shear stress more than the Newtonian case. An indent at the junction between positive and negative normal stresses may form at the neck which can further propagate neck thinning.

The fact that the indentation observed can be a normal stress effect, one may suspect there can be edge fractures in fluid flow. This allows one to model stability for capillary stable bridges with edge fractures as a power-law decay in time. In certain embodiments, even with the power law decay, both the Newtonian and viscoelastic capillary bridges may be on the order of 1 second to destabilize for a fixed moderate torsion. This can be enough time for a chemically modified surface to counteract the surface tension induced by the torsion. On the other hand, in certain embodiments, the power lay decay can make the capillary bridge stability sensitive to translational shear stress, and thus asymmetry anchoring surfaces may not be as effective which are expected to undergo more than 90 degrees of torsion. For embodiments with a morphological-based microstructure anchoring point(s), such as a regular array of pillar without chemical modification, fluid flow through the pinning microstructure can counteract the torsional effect sufficiently to mitigate capillary bridge disruption.

### Isocline Binary Capillary Bridge Systems

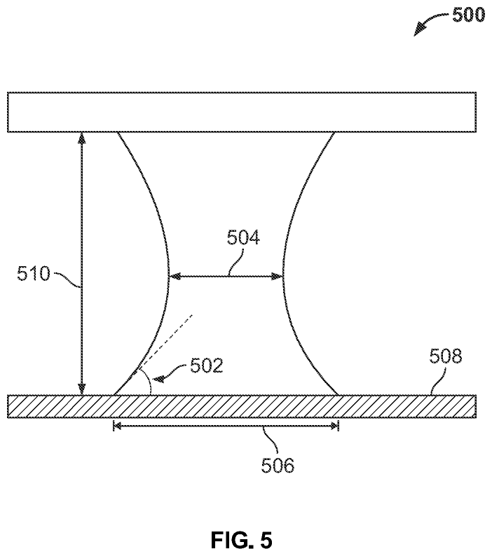

Referring now to FIG. 5, an embodiment of a capillary system 500 is illustrated including a receding contact angle 502, a capillary bridge waist 504, a diameter 506 of the capillary bridge anchoring microstructured surface 508, and a length 510 of the capillary bridge.

One of skill in the art may appreciate that it can be advantageous in certain embodiments to set as a capillary bridge stability criterion where the receding contact angle 502 remains approximately constant. This may be advantageous because when the receding contact angle 502 starts to change the capillary bridge may be unstable and may converge to a condition where the capillary bridge length 510 divided by the capillary bridge diameter 506 approaches zero, and where the capillary bridge waist 504 divided by the capillary bridge diameter 506 approaches zero. This may be known as a capillary bridge detachment condition and may cause failure of the capillary bridge. It should be noted that in both failure conditions, the contact angle approaches or goes to zero, i.e., the surface becomes wetting (or in this case dewetting, because the forces are in the opposite direction of gravity).

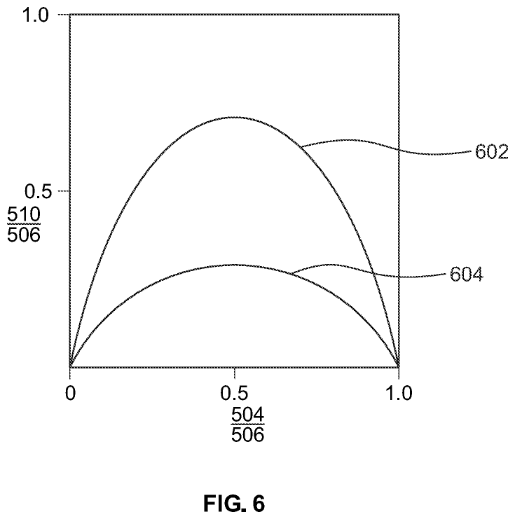

In certain embodiments, any particular material of the surface may only provide one value for the receding contact angle 502 where the capillary bridge is stable, which will describe a curve 602 in FIG. 6 where the receding contact angle is taken to be a constant value. In FIG. 6, the stable contact angle may be an isocline curve 602. The ordinate and abscissa of the curve are ratios of dimensions given in FIG. 5.

It should be noted, for embodiments with relatively smooth materials and fixed liquid, these isocline curves will fall between the maximum stable isocline curve 602 and the minimum stable isocline curve 604 and may have the general shape depicted in FIG. 6. One of skill should appreciate that there is no guarantee all the points on an isocline curve will be populated, since the surface tension of the fluid may set limits on the minimum value of the capillary bridge waist 504, but all stable points will be on that isocline. This is the case for the same reason the intrinsic contact angle of a drop on a single surface is approximately constant regardless of the volume of the drop.

For the binary capillary bridge system presented below in the tables, mineral oil and water will be used. Mineral oil is miscible with water but not soluble in water. Thus, when mixed the system will stay in a homogenous state longer than water and corn oil. The surface tension of mineral oil is between 26.1 and 29.3 mN m−1, compared to 32 mN m−1 for corn oil, whereas the surface tension of water is 72 mN m−1. This system was chosen because in biological systems the phobic phase is generally miscible with the philic phase. This may be due to the emulsifying presence of proteins. The large difference in surface energies may lead to strong phase separation on the microstructured surface, and capillary bridge stabilization. In a static environment, a water-mineral oil system will eventually separate.

TABLE 21
Stability Isocline for Smooth PLA Anchoring Surfaces with
water Capillary Bridge W = 504, D = 506, H =
506 from FIG. 5; Capillary Bridge contact angle = 14.7 degrees

| W/D | H/D |
|---|---|
| 0.22 | 0.46 |
| 0.31 | 0.49 |
| 0.37 | 0.52 |
| 0.46 | 0.48 |
| 0.57 | 0.44 |
| 0.66 | 0.41 |
| 0.79 | 0.30 |
| 0.91 | 0.16 |
| 0.98 | 0.07 |

TABLE 22
Stability Isocline for 160 CP PLA Anchoring Surfaces with water
Capillary Bridge; Capillary Bridge contact angle = 9.1 degrees

| W/D | H/D |
|---|---|
| 0.18 | 0.38 |
| 0.27 | 0.42 |
| 0.35 | 0.47 |
| 0.49 | 0.40 |
| 0.55 | 0.36 |
| 0.64 | 0.34 |
| 0.75 | 0.22 |
| 0.87 | 0.11 |
| 0.97 | 0.03 |

TABLE 23
Stability Isocline for Smooth PLA Anchoring Surfaces with
water Capillary Bridge W = 504, D = 506, H =
506 from FIG. 5; Capillary Bridge contact angle = 9.5 degrees

| W/D | H/D |
|---|---|
| 0.21 | 0.39 |
| 0.30 | 0.45 |
| 0.39 | 0.46 |
| 0.51 | 0.43 |
| 0.57 | 0.41 |
| 0.66 | 0.36 |
| 0.77 | 0.28 |
| 0.85 | 0.19 |
| 0.95 | 0.11 |

TABLE 24
Stability Isocline for 160 CP PLA Anchoring Surfaces
with 90:10 water-mineral oil capillary bridge

| W/D | H/D |
|---|---|
| 0.13 | 0.16 |
| 0.21 | 0.23 |
| 0.30 | 0.32 |
| 0.41 | 0.33 |
| 0.52 | 0.27 |
| 0.65 | 0.21 |
| 0.77 | 0.14 |
| 0.84 | 0.10 |
| 0.97 | 0.05 |

TABLE 25
Stability Isocline for 160 CP PLA Anchoring Surfaces
with 50:50 water-mineral oil Capillary Bridge;
Capillary Bridge contact angle = 1.2 degrees

| W/D | H/D |
|---|---|
| 0.15 | 0.13 |
| 0.26 | 0.19 |
| 0.38 | 0.31 |
| 0.46 | 0.29 |
| 0.55 | 0.26 |
| 0.67 | 0.22 |
| 0.75 | 0.16 |
| 0.83 | 0.09 |
| 0.91 | 0.03 |

All of the data provided above fall on the predicted isocline curve. It may also be appreciated that embodiments with lower capillary bridge contact angle may correlate with more stable capillary bridges. This may be expected because the failure condition is when the contact angle approaches or goes to zero, so if its stable near the failure condition it may have a slower progression to failure. Additionally, mixed water-mineral oil capillary bridges have a significantly lower capillary bridge contact angle than oil or water, which were approximately the same. The higher content water-oil mixture was more stable than the mostly water mixture.

### Contact Angle vs Adhesion, Smooth vs Microstructured

In some embodiments, it may be beneficial to utilize a standard notion of adhesion as used herein. In some embodiments, there may be an interplay between microstructured contact angle and adhesion coefficient which is inverted for smooth surfaces. Microstructured (locally varying surface energy) contact angle may be fundamentally different from smooth (uniform surface energy) surface contact area. The latter may be generally understood as a reductionist concept, whereas the former may be understood as an emergent concept not anticipated by current reductionist theories of rheology and tribology.

For these reasons, it may be informative to use the term “intrinsic (Young's) contact angle” to refer to the contact angle with a pure substance with a uniform surface energy (on the micron scale) and the term “structured contact angle” to refer to the contact area made with a pure substance with a uniformly varying surface energy, and the term “apparent contact angle” to refer to any contact angle where the surface energy of the contacting surface is either randomly varying or incompletely characterized and specific to a particular setup.

If one defines Cbase as the attachment area of the capillary pillar to the surface, assume the area of a capillary pillar is proportional to the sum of forces acting on it, then Fbase(1)=Fgrav+Fattract(1)−Fattract(2) with the microstructured side down. If one flips the pair over, then Fbase,(2)=Fgrave+Fattract(2)−Fattract(1) with the microstructured side up. We may end up with the following:

C_{base}=½(C₁−C₂)

Where “Cbase” is the attachment area of the capillary bridge due to the adhesive force of the microstructure alone, and assuming the target surface with measured area C2 (smooth) is made of the same material as measured area C1 (microstructured). Here the plane projected (apparent) area is used for the microstructured surface. Cbase=0 when C1 is not microstructured. For smooth on smooth a third surface has to be used, and then the same subtraction as above is performed to give a nonzero value for Cbase.

If one now introduce the force balance equation as follows:

F_{cap}=[Aω_{micro}(rᵢⱼ)+Bω_{flat}(rᵢⱼ)]eᵢⱼ

where “Fcap” is the tension in the capillary bridge between a microstructured surface and a smooth surface of the same material, “A” is the attraction coefficient for the microstructured surface in units of force per unit capillary length, “B” is the repulsion coefficient of the microstructured surface or the attraction coefficient for the smooth surface, the two are positive definite and add to yield the total tension in the capillary bridge, “w_{micro}” is the inverse force per unit capillary distance for a capillary bridge formed between two microstructured surfaces divided by the capillary force at capillary length 100 microns to give inverse units of force normalized to the force at capillary length 100 microns, “w_{flat}” is defined similarly for the smooth surface, rᵢⱼ=|rᵢ−rⱼ| is the vertical component of the capillary length which means “w” is to be measured with respect to the length of the capillary bridge with respect to gravity, and not the actual distance if the system is tilted,

$${e}_{ij} = \frac{{\overline{r}}_{i j}}{{r}_{ij}}$$

which corrects for the system tilt, r̅ is the vector of tilt, for no tilt eᵢⱼ=1. Then, A has a quantifiable definition as follows:

A:=ω_{micro}⁻¹(rᵢj)[eᵢⱼ⁻¹F_{cap}−Bω_{flat}(rᵢⱼ)]

Or a definition for no tilt:

A:=ω_{micro}⁻¹[F_{cap}−Bω_{flat}]

The target is a solution cast surface of the same material as the microstructured surface. Positive vertical force was measured by stacking shims around a water drop positioned on a digital scales (+/−1 mg) until the level of the shims was level with the drop surface, then shims were removed in increments indicated above, and tarred and the a disk was slowly lowered on the drop and the compressive force measured in increments, and the maximum force recorded just prior to contact with the shims. Contact was noticeable as a discontinuity in the displacement force curve. The non microstructured surface was a disk of gold-plated nickel.

TABLE 26
Attraction Coefficient (normalized force per capillary
length), Chase vs Contact Angle for Capillary
Bridge, Smooth on Smooth various materials

| A (attraction | Chase (norm | Intrinsic Contact |
|---|---|---|
| coefficient) | attachment area) | Angle (deg) |
| 2.9 +/− 5% | 53 +/− 5% | 42 +/− 2 |
| 2.6 | 31 | 52 |
| 2.0 | 21 | 73 |
| 1.4 | 10 | 96 |
| 0.9 | 0.5 | 115 |

TABLE 27
Attraction Coefficient (normalized force per capillary length),
Chase vs Contact Angle for Capillary Bridge, Chemically modified
or different materials, 160 CP with same smooth

| A (attraction | Chase (norm | Intrinsic Contact |
|---|---|---|
| coefficient) | attachment area) | Angle (deg) |
| 25.4 +/− 5% | 315 +/− 5% | 155 +/− 2 |
| 21.2 | 176 | 132 |
| 17 | 97 | 109 |
| 10.7 | 53 | 91 |
| 6.9 | 46 | 79 |

The relationship between capillary bridge attraction coefficient and material surface contact angle for smooth surfaces may be approximately the inverse of the microstructured surfaces. Smooth surfaces may increase contact angle decreasing attraction coefficient. Microstructure surfaces may increase contact angle increasing attraction coefficient. This is a truly astounding result.

Now turning to examples of the present invention.

### Example 1. Mushroom Profile Hierarchical Microstructured Surface

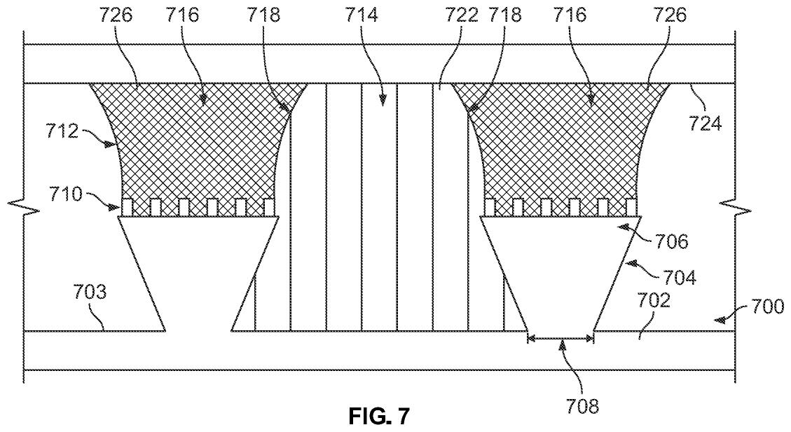

Referring to FIG. 7, a microstructured surface 700 may include a substrate 702, a zeroth order microstructure 704, where the diameter 706 of the top surface of the zeroth order microstructure is from 10 to 50 percent larger than the base diameter 708 of the zeroth order microstructure at the substrate surface. In some embodiments the diameter 706 of the top surface of the zeroth order microstructure is from 10 to 100 percent larger than the base diameter 708, and may be from 10 to 200 percent larger than the base diameter in other embodiments. In certain embodiments, the aspect ratio of zeroth order microstructure 704, (i.e. height to mean diameter) may be from 0.5 to 10, in the range of 10 to 1000 microns. Some embodiments may include a first order microstructure 710, where the diameter is fixed between 1 and 100 microns and the aspect ratio is between 0.5 and 10. In some embodiments, contact with ionic compound fluid 712, comprising first component of saline 714 and second component of lipid or protein 716, may induce a Wenzel-Cassie interface along the saline component and lipid component boundary 718. Hydrophilic capillary bridge 722 may connect the microstructure substrate surface 703 to the target surface 724 and hydrophobic capillary bridges 726 connect the microstructure surface 703 to the target surface 724. The hydrophilic capillary bridges 722 may be interconnected, as are the hydrophobic bridges 726, and bridges 722, 726 may also interpenetrate, forming a highly pinned Wenzel-Cassie capillary bridge structure in certain embodiments.

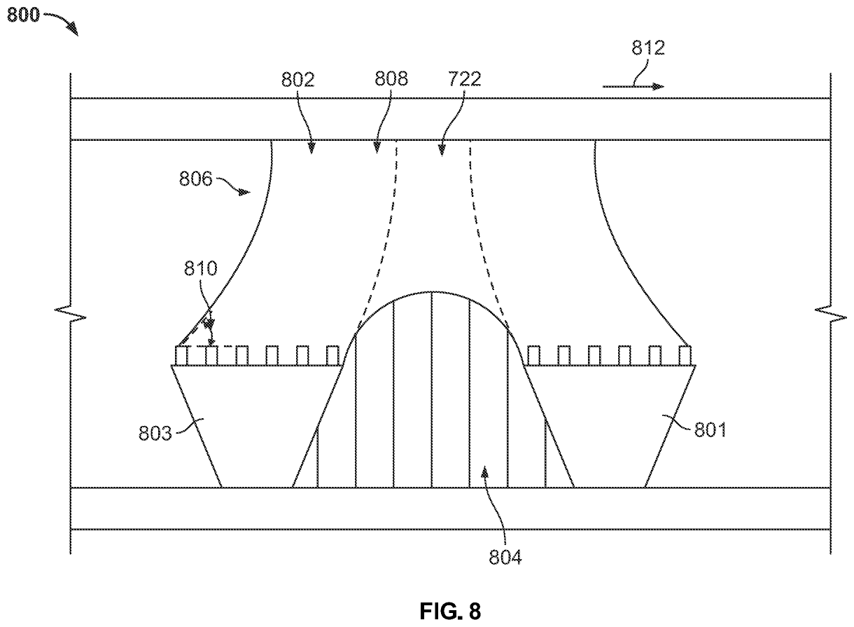

Regarding the depinning mechanism 800, with reference to FIG. 8, two adjacent hierarchical microstructures 801, 803 are depicted with first fluid 802 and second fluid 804. First the liquid-vapor interface 806 at the interface trailing edge 808 may deform until one reaches a limiting receding contact angle 810 on the detachment boundary. A dynamic phenomenon may start involving slip in the direction 812 of the liquid across the first order structure 801, 803 bridge between two microstructures breaking the aqueous capillary bridge 722, while the interface between two pillars may change from concave to convex, and may rise to keep constant capillary pressure, until pinch-off occurs. At the periphery, this leaves a small amount of liquid on the first order structure in the interior of the interaction volume; this action may lead to phase mixing in some embodiments.

In certain embodiments, there may be an interesting dynamic aspect which is significant because it may determine the shear force necessary to maintain the shear velocity. It may generally be understood that the larger the deposit volume the greater the shear force required to maintain the shear velocity. Also, the deposit volume may depend on the shear velocity, or more precisely the liquid bridge stretching velocity. The larger the stretching velocity, the larger the remaining volume may be after bridge failure. Thus, unlike Amonton friction, the force required to maintain slippage may be strongly velocity dependent. In fact, no aspect of the mechanisms disclosed here as novel can properly be termed friction.

### Example 2. Continuously Varying Zeroth Order Microstructure

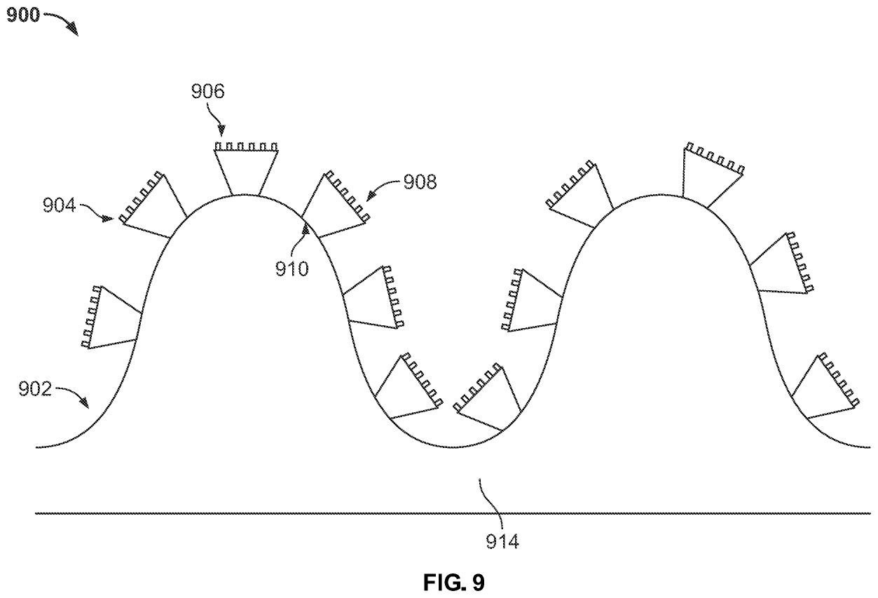

Referring to FIG. 9, a hierarchically microstructured device 900, comprises a zeroth order sinusoidal profile two-dimensional microstructure 902, a first order circular cross section flared or mushroom shaped pillar microstructure 904, and a second order straight circular cross section pillar microstructure 906, wherein the first order microstructure is positioned orthogonally to a tangent to the zeroth order microstructure 902. The central axis of the first order microstructures 904 may be positioned in a square grid in a projection to the substrate 914. The second order microstructure base centers may be positioned in a square grid on the top ends 918 of the first order microstructures. The first order microstructures may have a first diameter 908 larger than the second diameter 910.

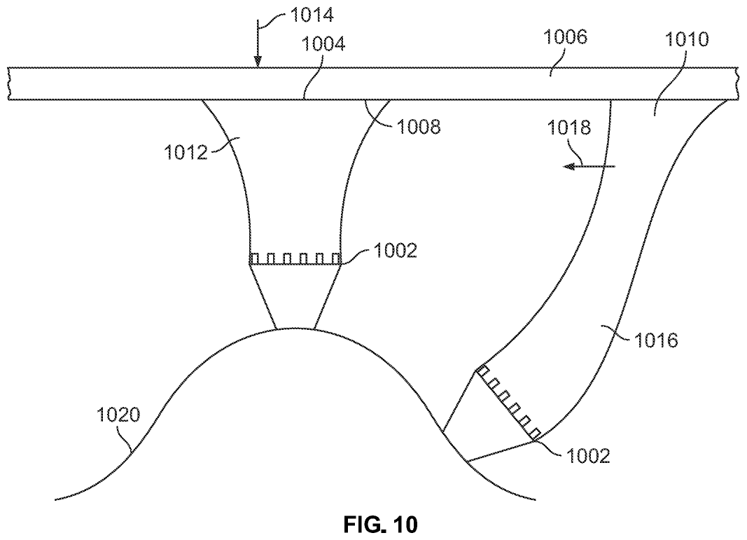

Referring to FIG. 10, in certain embodiments, lateral and vertical restorative forces may be developed which are depicted. A capillary bridge 1012, 1016 may extend from the distal ends 1002 to a point 1004 on the target surface 1006 at first location 1008 or at second location 1010. When the capillary bridge 1012 is attached at first location 1008 the capillary force may be mostly directed in a vertical vector (normal to surface) 1014. When the capillary bridge 1016 is attached at the second location 1010 the capillary force may be mostly directed laterally (horizontal to surface) 1018. The proportion of vertical and lateral capillary forces for a particular capillary bridge type may be determined by its position on the zeroth order microstructure 1020. Note, that when the capillary bridge 1016 is in the position 1010 the length of the capillary bridge 1016 may be longer than the length of the bridge when the capillary bridge 1012 is positioned in first position 1008.

### Example 3. A Microstructure Device with Large Contact Angle Hysteresis

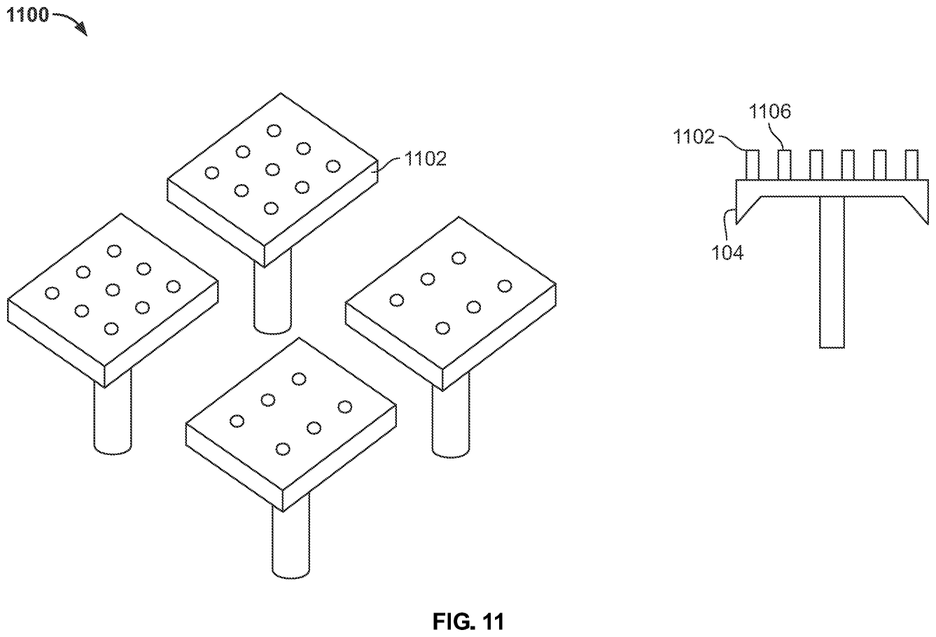

Referring to FIG. 11, a doubly reentrant microstructured device 1100 may have dramatically different advancing pinning and recession de-pinning dynamics for capillary bridges. The zeroth order microstructure 1102 may be a T-shaped pillar with a lip 1104 arranged in a square array. The first order microstructure may be a straight circular pillar 1106 arranged in a square array.

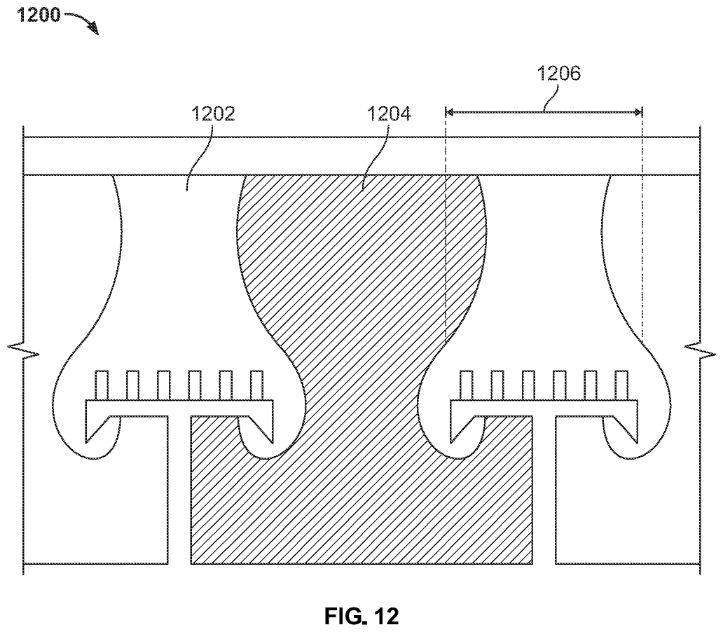

Referring to FIG. 12, a dominant pinning mechanism 1200 is illustrated for the device of FIG. 11 wherein a phobic liquid phase 1202 and a philic liquid phase 1204 may be mutually pinning. The width dimension 1206 can range from 1000 microns down to 10 microns.

To optimize the microstructure for capillary pinning, six structural parameters may be understood to generally influence the three key wetting properties: Pillar width, pillar height, lip depth, cap thickness, cap width, and the system scale 1206 (where 1206=100 microns).

Optimization may include balancing the wetting properties of parameters that act antagonistically. First, to increase the contact angle hysteresis, the cap width may be increased; but this may increase the critical pressure and energy barrier. Second, to increase the critical pressure, the system scale may be reduced; but this may reduce the energy barrier.

### Example 4. Reverse Bifurcating Capillary Bridge Microstructure

The Gecko foot is able to grasp surfaces using Van der Waals forces generated at the tips of bifurcating micro filaments. In this case, the microstructure of the filaments bifurcates toward the target surface. Referring to the reverse bifurcating capillary bridge microstructure of this example, when in contact with a liquid coated target surface, bifurcating capillary bridges may be formed that bifurcate away from the target surface.

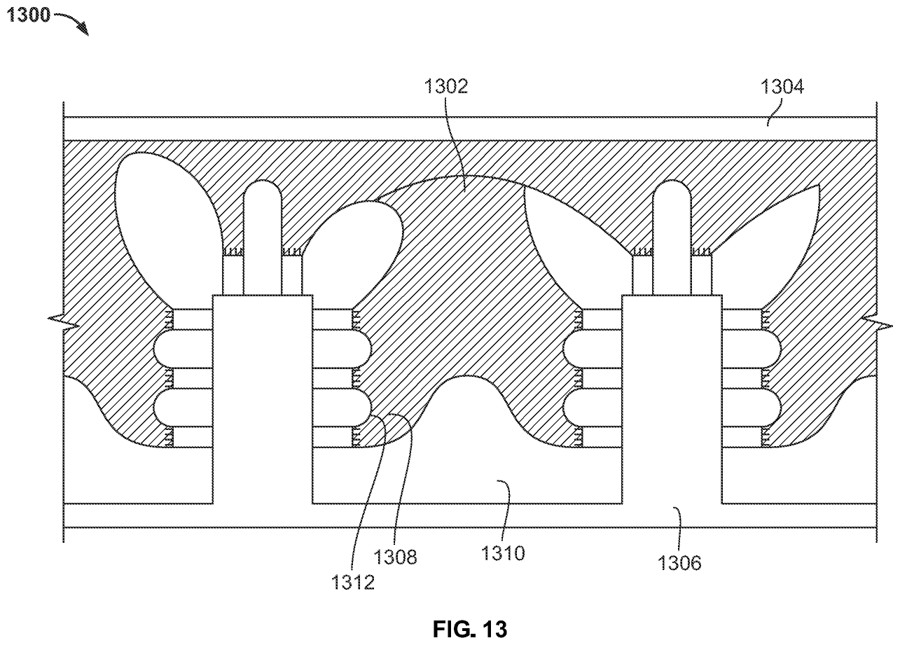

Referring to FIG. 13, an interface 1300 comprised of a binary fluid 1302 between a target surface 1304 and a microstructured surface 1306 is illustrated. The two phases of binary fluid 1302 may separate into capillary bridges 1308, 1310 forming Wenzel-Cassie juxtapositions of philic and phobic phase and anchoring points. Note, capillary bridges 1308 form bifurcations 1312. These capillary bridges 1308, 1310 may have an internal tension which acts much like the fibers on a Gecko foot, providing adhesion between the microstructure of the Gecko and the target surface.

It should be appreciated from this example, that the more levels of hierarchy on the microstructured surface the bifurcated the capillary bridges will be, in general. Consequently, the entanglement between capillary bridges 1308, 1310 generate a stronger restorative force in response to lateral translation.

Thus, although there have been described particular embodiments of the present invention of a new and useful CAPILLARY BRIDGE ENHANCED FLUID GRIP DEVICE it is not intended that such references be construed as limitations upon the scope of this invention except as set forth in the following claims.

What is claimed is:

1. A microstructured surface for adhering to a target surface, the micro structured surface comprising:
a substrate having a microstructure pattern disposed thereon wherein the microstructure pattern comprises a plurality of microfeatures configured to interact with the target surface via a fluid interface, wherein the interface forms at least one capillary bridge having a first end and a second end, the first end contacting at least one of the plurality of microfeatures and the second end contacting a portion of the target surface, and wherein the microstructure pattern is configured to stabilize the capillary bridge.

2. The microstructured surface of claim 1, wherein at least a portion of the plurality of microfeatures project from the substrate.

3. The microstructured surface of claim 1, wherein the fluid interface is a compound fluid having a first fluid component and a second fluid component such that the first fluid component has a higher surface tension than the second fluid component, and said first and second fluid components separate into at least two capillary bridges between the microstructured surface and the target surface.

4. The microstructured surface of claim 3, wherein the compound fluid comprises two immiscible liquids.

5. The microstructured surface of claim 4, wherein a lateral displacement of the microstructured surface with respect to the target surface is resisted by a lateral restorative force generated by at least one of the two capillary bridges.

6. The microstructured surface of claim 3, wherein the at least two capillary bridges mutually stabilize their capillary forces to generate a lateral restorative force that exceeds a lateral restorative force of the same two capillary bridges when exposed to a fluid of a single phase.

7. The microstructured surface of claim 1, wherein the contact angle hysteresis of the microstructured surface is greater than 5 degrees as determined by sessile drop assay.

8. The microstructured surface of claim 1, wherein the microstructured surface is capable of generating a suction force against the target surface of 10 mg/cm² of apparent surface area.

9. The microstructured surface of claim 1, wherein the microstructured surface induces Schallamach waves of the target surface, and the plurality of microfeatures engage said Schallamach waves.

10. The microstructured surface of claim 1, wherein the microstructured surface induces eigen wrinkles on the target surface, and the plurality of microfeatures engage said eigen wrinkles.

11. The microstructured surface of claim 1, wherein the plurality of microfeatures are configured to form a Wenzel-Cassie interface with the target surface.

12. The microstructured surface of claim 3, wherein the plurality of microfeatures are configured to form a Wenzel-Cassie interface with the target surface.

13. The microstructured surface of claim 12, wherein the Wenzel-Cassie interface mutually reinforces the at least two capillary bridges.

14. The microstructured surface of claim 1, wherein the plurality of microfeatures comprise a first microfeature and a second microfeature wherein the second microfeatures is disposed about a top surface of the first microfeature.

15. The microstructured surface of claim 1, wherein the dimensions of the first microfeature are from 10 to 1000 microns, and the dimensions of the second microfeature are from 1 to 100 microns.

16. The microstructured surface of claim 15, wherein the first microfeature comprises an aspect ratio of height to diameter from 0.5 to 10.

17. The microstructured surface of claim 15, wherein the second microfeature comprises an aspect ratio of height to diameter from 0.5 to 10.
